(19) United States
(12) Patent Application Publication
(10) Pub. No.: US 2025/0112167 A1
(43) Pub. Date: Apr. 3, 2025

(54) SEMICONDUCTOR DESIGN LITHOGRAPHIC SEAM IMPLEMENTATION METHODOLOGY FOR ADVANCED TECHNOLOGIES

(71) Applicant: Intel Corporation, Santa Clara, CA (US)

(72) Inventors: Kimberly Pierce, Beaverton, OR (US); Marni Nabors, Portland, OR (US); Nidhi Khandelwal, Portland, OR (US); Keith Zawadzki, Portland, OR (US)

(73) Assignee: Intel Corporation, Santa Clara, CA (US)

(21) Appl. No.: 18/375,327

(22) Filed: Sep. 29, 2023

(51) Int. Cl. H01L 23/544; G03F 7/09; H01L 21/768; H01L 23/528; H01L 23/58

(52) U.S. Cl. CPC H01L 23/544; H01L 21/768; H01L 23/528; H01L 23/585; G03F 7/094; H01L 2223/54426

(57) ABSTRACT

An integrated circuit (IC) device includes one or more functional blocks spanning a lithographic seam between adjacent lithographic fields. A functional block includes multiple instances of a pattern, each instance corresponding to a different placement option for the functional block. The IC device may include multiple such functional blocks spanning lithographic fields. The lithographic seam (and the patterns otherwise located) may include lithographic assist features, such as registration marks and metrology structures. The multiple lithographic fields may be or include high numerical aperture extreme ultraviolet lithographic fields. The lithographic seam may interface with wafer finishing collaterals (such as guard rings).

### BACKGROUND

Ever more advanced devices provide a need for either or both of smaller device features and larger die sizes to support increasingly more complex designs. To reduce direct print patterning pitches, high numerical aperture extreme ultraviolet (high-NA EUV) lithography is likely to be required. The introduction of a high-NA anamorphic lens will reduce maximum field size (by half, for example) on layers patterned with this advanced EUV tooling and will require the exposure of multiple lithographic fields for die layers that previously needed only a single exposure. Larger die products are also expected to be needed to support a variety of products, such as those using large base die in multi-chip applications. Dies with large enough dimensions will need to be split into two or more lithographic fields to conform to tooling requirements based on the standard patternable single-lens field. The use of multiple lithographic fields on the same die provides a variety of difficulties, particularly at the seam between the fields within the active design.

New structures and techniques are required to enable the higher-resolution features and larger die sizes demanded by ever more sophisticated electronics systems and complexes.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, and 1C illustrate plan views of an example monolithic integrated circuit (IC) device, including a lithographic seam between regions of a substrate and with functional units placed over and across the lithographic seam, in accordance with some embodiments;

FIGS. 2A and 2B illustrate plan views of IC substrates with various lens field utilizations, both with IC devices spanning multiple lithographic fields and with lithographic fields spanning multiple IC devices, in accordance with some embodiments;

FIG. 3 illustrates a plan view of an IC substrate with IC devices spanning multiple lithographic fields and with lithographic fields spanning multiple IC devices, in accordance with some embodiments;

FIGS. 4A and 4B illustrate plan and isometric views of a substrate with IC devices and co-planar device and metallization layers spanning multiple lithographic fields, in accordance with some embodiments;

FIG. 5 illustrates a cross-sectional profile view of an IC device in a substrate having co-planar device and metallization layers in regions on both sides of a lithographic seam, in accordance with some embodiments;

FIGS. 6A and 6B illustrate plan views of etch rings and guard rings around active regions of IC devices, including in and through a lithographic seam, in accordance with some embodiments;

FIGS. 7A, 7B, and 7C illustrate cross-sectional profile views of an IC device in a substrate having co-planar device and metallization layers, including etch rings in a lithographic seam, in accordance with some embodiments;

FIG. 8 illustrates a cross-sectional profile view of an IC device in a substrate having co-planar device and metallization layers, including etch rings and a guard ring, in accordance with some embodiments;

FIG. 9 is a flow chart of methods or a process for forming an IC device having a lithographic seam in one or more layers thereof, in accordance with some embodiments;

FIG. 10 illustrates a diagram of an example data server machine employing an IC device having a seam between active regions using split lithographic fields, in accordance with some embodiments; and

FIG. 11 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranv ged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Integrated circuit (IC) die structures and techniques are described herein to enable improved layout efficiency of functional units adjacent and across a seam between adjacent lithographic fields of a monolithic die.

The introduction of advanced lithographic techniques leads to reduced lithographic field sizes in some contexts. As used herein, the term lithographic field indicates a region or area that is patterned in one exposure using the pertinent lithographic techniques. For example, for high numerical aperture extreme ultraviolet (high-NA EUV) exposures, particularly those using high-NA anamorphic lenses, the maximum field size is reduced by half relative to other lithographic techniques. For example, the maximum field size of high-NA EUV exposures, which may be needed to push direct printing feature patterns below 30 nm pitch, may be reduced from about 26 mm by 33 mm to about 26 mm by 16.5 mm for some photolithographic tooling. However, advanced products also require larger die sizes such that each die requires multiple lithographic fields for those layers of the fabrication process that use small field sizes. Any number of multiple lithographic fields per die may be used such as two, four, or more. It is noted that such multiple fields per die lithography is not necessarily needed for all layers of the fabrication process. Other layers may use one or fewer fields per die. For example, for those using high-NA EUV or other lithography techniques that require splitting a die into multiple fields, the lithographic seams discussed herein may be deployed.

Notably, placing a lithographic seam between adjacent fields (e.g., at mask field splits) of a single die provides a challenge for design efficiency and layout ease of use. The techniques and structures discussed herein provide a lithographic seam between adjacent fields for improved design efficiency and layout. As used herein, the term lithographic seam indicates a region of a layer of an IC die that includes lithographic assist features or structures and excludes active features or structures. For example, for a device layer, the active region of the IC die includes active device features or structures (e.g., channel materials, source and drain material, gate electrode, gate contacts, source and drain contacts, etc.) while the lithographic seam includes inactive features or structures that are used for lithographic assist and/or other non-active purposes. For a metallization layer, the active region of the IC die includes active features or structures (e.g., interconnect structures, such as wires in various layer and vias in and between layers, electrically coupled in one or more circuits (rather than floating, with only high-impedance connections to other structures)). For example, lithographic assist features or structures include registration marks, measurement features (e.g., metrology structures), and others. Other non-active purposes for such non-active or dummy features or structures include pattern fill and others.

The discussed lithographic seam may be between, e.g., standard-sized lithographic fields in a large die. The discussed lithographic seam may be at any layer or layers of an IC die that deploys reduced field size lithography, such as at device layers and lower metallization layers. As used herein, the term device layer includes any layer used to fabricate a device of the IC die such as a transistor, capacitor, or other active or passive device. The term metallization layer indicates a layer used to fabricate a via or metal line layer of the IC die. For example, advanced lithographic techniques that necessitate splitting a die into multiple fields may correspond to those layers having small features and/or tight pitches. Such patterning needs are typically found in some device layers and lower level metallization layers. As discussed herein, other layers may not need advanced lithographic techniques that necessitate die splitting into multiple fields. For example, higher level metal lines may cross the lithographic seam in layers other than those where die splitting is used.

Deploying such lithographic seams allows multiple fields (i.e., die masks) and provides design flexibility and improved functional unit layout adjacent and across lithographic seam boundaries. As used herein, the term functional unit indicates a part of an IC die that is used as a monolithic part of the IC die to implement one or more known functions, to provide a capability for the IC die, or the like. Notably, a functional unit is provided within an area of the IC die. The lithographic seams discussed herein may be characterized as a die mask zipper seam as the lithographic seam ties together fields of the die across a seam (e.g., similar to a zipper pattern). Rectilinear and nonlinear lithographic seams may be used in the embodiments discussed herein.

Functional units (e.g., intellectual property (IP) blocks) may be designed to include one or more placeholder segments that can be aligned with a lithographic seam. Functional units or blocks may be designed with as many segments as necessary to provide the desired layout flexibility, including placements overlapping the lithographic seam. The lithographic seam may have a minimal width and area cost, and the incorporated segments provide design flexibility while not requiring complicated jags in the seam or wasted space due to underutilization of overly overlapping lithographic fields. Such flexibility enables designer reuse in different product designs.

In addition to enabling large die exceeding standard-or half-field sizes, this layout flexibility may be employed to maximize the lens field utilization (LFU) of die which are smaller than standards sizes, but are not optimized to the half-field. Die cut lines that can be opportunistically tiled across die and through IP blocks and tied into existing finishing collaterals (such as guard rings) may minimize any drawbacks introduced by lithographic seam constraints.

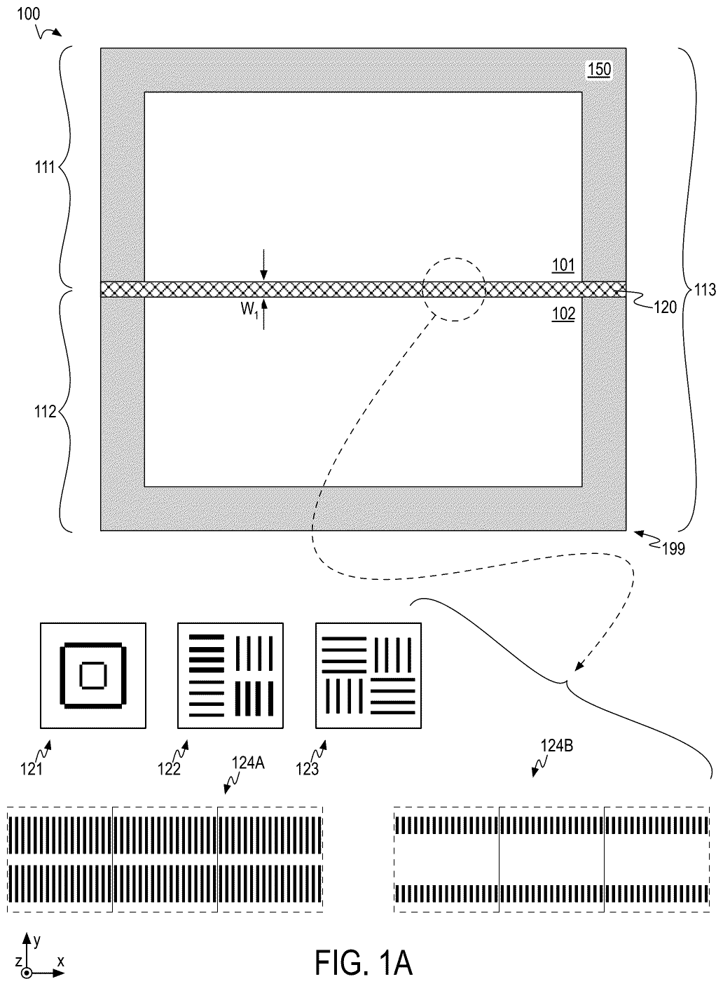

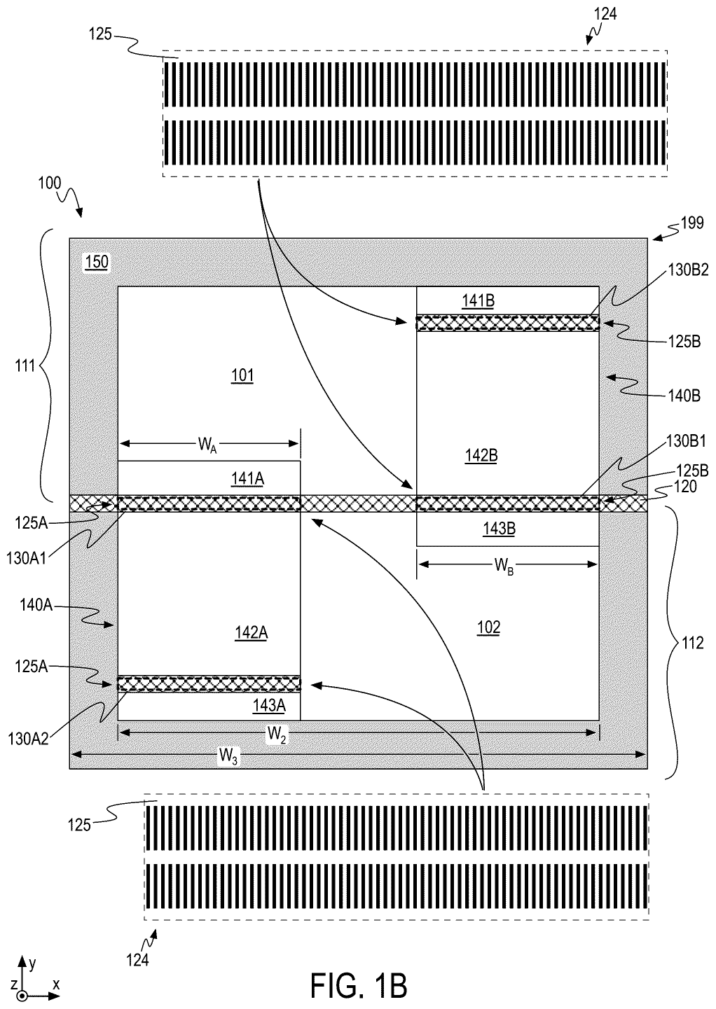

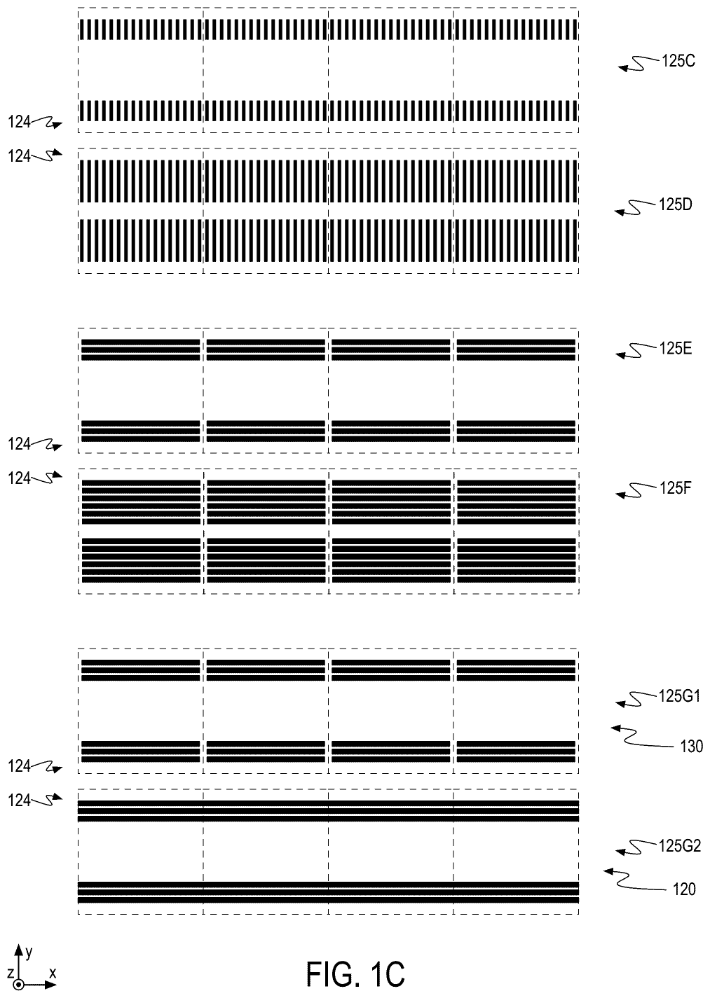

FIGS. 1A, 1B, and 1C illustrate plan views of an example monolithic IC device 100, including a lithographic seam 120 between regions 101, 102 of a substrate 199 and with functional units 140 placed over and across lithographic seam 120, in accordance with some embodiments. FIG. 1A shows at least a portion of substrate 199, which may extend in the x- and y-directions to any suitable size. Substrate 199 may be an IC die or wafer, and IC device 100 may be adjacent other devices on substrate 199. The portion of substrate 199 shown includes a first region 101 having one or more layers fabricated using a first lithographic field 111 and a second region 102 having those same one or more layers fabricated using a second lithographic field 112. As shown, a lithographic seam 120 separates region 101 of lithographic field 111 and region 102 of lithographic field 112. As shown, in some embodiments, regions 101, 102 are substantially rectangular. In some embodiments, regions 101, 102 are each abutted against lithographic seam 120. Regions 101, 102 are abutted against lithographic seam 120 such that regions 101, 102 and lithographic seam 120 share a boundary defined by lithographic seam 120

As discussed, a lithographic field indicates an area or region exposed using a single lithographic exposure. For example, a photoresist layer for a layer of region 101 is exposed with a single lithographic exposure using a corresponding reticle or mask. The same photoresist layer for the layer of region 102 is then exposed with a different lithographic exposure, sometimes using a different reticle or mask. The subsequent fabrication processing for the applicable layer (or layers) is then performed using the patterned photoresist as patterned with the two different fields and reticles to provide the layer of substrate 199 such that a layer includes a patterned material, a patterned implantation, or other feature. Such subsequent fabrication processing may use the patterned photoresist in any suitable context such as etching underlying layers to pattern them, to provide a trench or via for subsequent fill, providing an implant mask, and so on. Such fabrication operations are known in the art and are not discussed at length herein. Notably, the resultant processing uses the patterned photoresist to provide corresponding features (of a layer of substrate 199) as defined by the photoresist pattern.

In regions 101, 102, such layers that deploy lithographic seam 120 include active or functional features or structures therein. As used herein, the term functional feature or structure indicates a component or material that is deployed as part of operable functional unit(s) of regions 101, 102 of IC device 100. The functional feature or structure may be a component of a transistor or other device, a via or metal line interconnecting devices, or the like. In contrast, non-functional features or structures are those that are not part of operable functional unit(s) of regions 101, 102 of IC device 100. Such non-functional features or structures may have similar materials or dimensions but are not operable. Such non-functional features or structures may be deployed for pattern fill (i.e., so the wafer being fabricated has a more uniform surface) or as lithographic assist features or as dummy features.

For example, for the layers that deploy lithographic seam 120, lithographic seam 120 may include non-functional structures, such as lithographic assist features 121, 122, 123. In the illustrated embodiments, lithographic assist feature 121 is a registration mark having a number of concentric patterns such that a lithography tool may detect lithographic assist feature 121 in a subsequent lithographic patterning. For example, at the subsequent lithographic patterning, the resist may be partially transparent such that lithographic assist feature 121 may be detected, its location mapped, and the resultant mapping of the wafer may be used to improve lithographic performance. Also as shown, lithographic assist features, 122, 123 may include metrology or measurement patterns to verify the performance of the current lithographic operations. Such metrology or measurement patterns may be used after resist develop (e.g., measurements may be made using the patterned photoresist) and/or or the metrology or measurement patterns may be used after subsequent processing (e.g., metal lines or other features or components may be measured). In the illustrated example, lithographic assist features, 122, 123 include tight pitched horizontal and vertical line features. However, any lithographic assist features 121, 122, 123 may include any suitable metrology or measurement patterns, such as isolated line features, tight pitched vias, isolated vias, other patterns, and so on.

Lithographic seam 120 may include other non-functional structures (additionally or in the alternative), such as dummy features 124 (e.g., features 124A, 124B) or other patterning assist features. Dummy features 124 (or “dummies” or “dummification”) may be inactive structures that provide feature density in a region otherwise sparsely populated with features (e.g., to be etched, etc.). Some IC devices have significant regional variation between active feature densities, for example, with relatively high density in some regions having arrays of transistors (e.g., for memory or processing) and with relatively low density in some regions of interconnect routing or otherwise between active features, e.g., in a lithographic seam.

Without dummification, such density variation degrades etch and critical dimension (CD) control when patterning devices, which may consequently degrade IC performance. With wide pattern density, etch control may not have enough signal to determine when etch should stop, which may require over-etch margin to control CDs and may still cause transistor and/or other CD variation in IC manufacturing. Patterned dummification in areas with low transistor density may enable satisfactory etch signaling for end-point and CD control. Filling otherwise-blank fields away from an array with dummification may minimize density variation and provide macro loading (e.g., across a die or wafer). Such dummification can cover portions of an IC wafer, as needed, to provide improved etch control, e.g., superior end-pointing. Other dummies may be used at the edges of an array (or other region of feature density) to maintain consistent micro loading. Dummification there (e.g., at edges between regions with density variation) ensure chemistries (e.g., etchant concentrations) at array edges are matched to those internal to the array. Dummies can prevent excessive reactant gradients at array perimeters during etch processing.

Dummy features 124 may be deployed in lithographic seam 120 as necessary or desired, for example, to provide feature density between regions 101, 102 (e.g., for macro loading) and/or adjacent regions 101, 102 (e.g., for micro loading). Dummy features 124 in lithographic seam 120 may have a symmetry across a discontinuity between dummy features 124. For example, as shown in FIG. 1A, dummy features 124 exposed in lithographic field 111 may be across a line of discontinuity from dummy features 124 exposed in lithographic field 112, e.g., where the line of discontinuity extends in the same direction as, and along a centerline of, lithographic seam 120. In the example of FIG. 1A, seam 120 (and the line of discontinuity between dummy features 124) extends in the x direction. Other configurations are possible.

Dummy features 124 may span most of lithographic seam 120, as do features 124A in FIG. 1A. Lithographic seam 120 may include other features (such as lithographic assist features 121, 122, 123), and dummy features 124 may have a gap (e.g., of discontinuity between dummy features 124) with the other features (e.g., features 121, 122, 123) in the gap between dummy features 124, e.g., features 124B in FIG. 1A. Lithographic seam 120 may include other features (e.g., features 121, 122, 123) in the gap between either or both of dummy features 124A, 124B. In some embodiments, a larger gap (e.g., as between features 124B) corresponds to more other features (e.g., features 121, 122, 123) in lithographic seam 120. Lithographic seam 120 may include either, both, or neither of dummy features 124A, 124B, as well as other features. Lithographic seam 120 may include lithographic assist features (such as features 121, 122, 123), but such features may be adjacent seam 120 (additionally or alternatively to features in seam 120) and throughout regions 101, 102. In some embodiments, lithographic seam 120 includes lithographic assist features (such as features 121, 122, 123) elsewhere in seam 120, e.g. to the right or left of dummy features 124 (e.g., in the positive or negative x-direction). In some embodiments, seam 120 is mostly blank or empty, e.g., with few inactive features.

Regions 101, 102 may include active features (e.g., in a device layer and lower metallization layers) requiring high-resolution lithography and other active features (e.g., higher metallization layers) with less-stringent resolution requirements. In some embodiments, lithographic fields 111, 112 (including regions 101, 102) include high-NA EUV lithographic fields. The resolution provided by such photolithography may advantageously enable very fine features, such as narrow device dimensions and pitches. In some embodiments, lithographic seam 120 includes non-functional structures (such as lithographic assist features 121, 122, 123) in a same co-planar device or metallization layer(s) that include(s) active features of region 101 in lithographic field 111 and active features of region 102 in lithographic field 112. Such, e.g., non-functional structures in seam 120 adjacent regions 101, 102 may assist in the processing, for example, lithography, of regions 101, 102 within lithographic fields 111, 112. Non-functional lithographic assist features 121, 122, 123 (and others) may be necessary for satisfactory fabrication of fine-resolution devices 100. In some embodiments, region 101 is within lithographic field 111, region 102 is within lithographic field 112, and both regions 101, 102 are within lithographic field 113. Regions 101, 102 in lithographic field 113 may be exposed with a single lithographic exposure, e.g., for patterning larger features, such as high-power interconnects. In some embodiments, a co-planar metallization layer (e.g., an upper metallization layer) of regions 101, 102 is patterned by a single exposure of lithographic field 113.

Lithographic seam 120 may have a minimal width W₁ (e.g., in the y-dimension, between regions 101, 102). Such a minimal width may minimize the area cost of lithographic seam 120. In some embodiments, lithographic seam 120 has a width W₁ of 10 μm or less. The area occupied by lithographic seam 120 may correspond to an overlapping area of lithographic fields 111, 112, and a minimum overlap area of lithographic fields 111, 112 (e.g., to pattern the non-functional structures in seam 120 (such as lithographic assist features 121, 122, 123)) may require a minimum width W₁ of seam 120. In some embodiments, a minimum width W₁ of seam 120 is 15 μm. In some embodiments, a minimum width W₁ of seam 120 is set by a desired size of non-functional structures in seam 120, such as lithographic features. In some such embodiments, a minimum width W₁ of seam 120 is 20 μm.

In some embodiments, IC substrate 199 and/or IC device 100 includes a border or other area or region 150 beyond or outside of regions 101, 102. In some embodiments, border region 150 includes non-functional structures. In some such embodiments, such non-functional structures in border region 150 are fabricated using the exposure(s) of lithographic field(s) 111 and/or 112. In some embodiments, as shown, lithographic seam 120 extends into border region 150. In some embodiments, lithographic seam 120 includes non-functional structures (such as lithographic assist features 121, 122, 123) in border region 150. In some embodiments, border region 150 is a buffer or spacer region between active, functional structures in IC device 100 (e.g., in regions 101, 102) and other devices 100. In some embodiments, border region 150 is a region between devices 100 and available as a singulation region (e.g., for a mechanical saw, laser scribe, singulation etch, etc.).

Substrate 199 may include any suitable material or materials. Any suitable semiconductor or other material can be used. Substrate 199 may be any suitable substrate, such as a wafer, die, etc. Substrate 199 may include a semiconductor (or other) material that transistors can be formed out of and/or on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. Substrate 199 may be a silicon-on-insulator (SOI) substrate. Substrate 199 may also include metals, dielectrics, dopants, and other materials commonly found in IC substrates.

FIG. 1B illustrates a plan view of IC device 100 having circuit block or functional unit 140 adjacent and across lithographic seam 120, overlapping with first and second regions 101, 102 on either side of seam 120. As discussed, IC device 100 may include a number of functional units 140 in one or both of regions 101, 102 or lithographic fields 111, 112 of IC substrate 199. As discussed further herein, functional units 140 include co-planar device layers and a number of co-planar metallization layers. As used herein, co-planar layers are layers that are aligned in the lateral plane (i.e., the x-y plane). The co-planar layers of functional units 140 and regions 101, 102 are formed in the same operations using the same resist layer, material layer(s), deposition process(es), etc., and are therefore co-planar. First region 101 in lithographic field 111 and second region 102 in lithographic field 112 include active, functional structures and are separated by lithographic seam 120, which includes non-functional structures in the co-planar layers. Examples of such non-functional structures are illustrated as lithographic assist features 121, 122, 123 and may include any non-functional features or structures discussed herein. Such non-functional features or structures are co-planar with the functional features or structures for the same reasons discussed above: they are formed in the same operations using the same resist layer, material layer(s), deposition process(es), etc., as those used to form the functional devices of regions 101, 102, including in functional units 140.

IC device 100 includes a lithographic seam 120 (e.g., die mask zipper), for example, to enable the use of multiple lithographic fields 111, 112 for co-planar layers in regions 101, 102. Blocks or units 140 may each include multiple segments 130 having the same non-functional structures (e.g., features 121, 122, 123, 124, etc.) of seam 120 to provide product floor plan flexibility in the layout of functional units 140 and regions 101, 102 for those layers using multiple lithographic fields and reticles without disrupting accepted lens field utilization (LFU), or lithographic field and reticle field size, at all other layers (e.g., those layers that do not require multiple fields per die). Lithographic seam 120 may maintain a minimal footprint to reduce waste in the layout. In some embodiments, for layers that require splitting a die into lithographic fields (e.g., for high-NA EUV layers), the design specification and validation of IC device 100 and/or substrate 199 requires lithographic seam 120 (e.g., a die mask zipper) to delineate where fields (and corresponding masks) are split within the design. In some embodiments, lithographic seam 120 is a region placed in accordance to the required process specification. For example, layers having lithographic seam 120 may or may not be drawn by design such that, when not drawn by design, the relevant features patterned in lithographic seam 120 may be added during mask preparation. In some embodiments, lithographic seam 120 includes some features drawn by design and other features patterned in lithographic seam 120 are added, e.g., by a non-design group, during layout or mask preparation.

It is noted that the layout of IC die, given the requirement for multiple lithographic fields 111, 112 and the consequent lithographic seam 120, may be more constrained in the placement of circuit blocks or units 140. Without the limitation of lithographic seam 120 and multiple lithographic fields 111, 112 being necessary, functional units 140 may be more flexibly placed within IC device 100. Functional units 140 may be intellectual property (IP) cores or IP blocks, e.g., circuit blocks designed to provide a particular function or capability within IC device 100 and to be reused within various different devices 100. Functional unit 140 may be designed and deployed with multiple segments 130 within unit 140, and each segment 130 may enable a corresponding one of multiple placements of unit 140 relative to seam 120. The arrangement of non-functional structures (e.g., in a pattern 125) in seam 120 may be required (e.g., by a design, layout, or process specification and/or design rule, e.g., for alignment, metrology, pattern fill, etc.). The arrangement of non-functional structures (e.g., in a pattern 125) in segment(s) 130 may be matched to that of seam 120 to facilitate alignment with segment 130 in seam 120 (and functional unit 140 over seam 120). Each segment 130 may be deployed having the same non-functional features (e.g., features 121, 122, 123, 124, etc.) and in a same pattern 125 of non-functional structures, to enable any of multiple placements of unit 140 relative to seam 120. For example, functional unit 140 may be positioned in any position over seam 120 where one of segments 130 (and the corresponding pattern 125) in unit 140 is aligned to the same pattern 125 of non-functional structures in seam 120.

Lithographic seam 120 and functional unit 140 together include a group of any of features 121, 122, 123, 124 (and/or other non-functional structures) in a certain pattern 125 where seam 120 and unit 140 overlap. In some embodiments, the group of non-functional structures in pattern 125 include registration marks and metrology structures. In some embodiments, the group of non-functional structures in pattern 125 include dummy structures. Functional unit 140 includes multiple segments 130 with matching groups of non-functional structures in the same pattern 125. The non-functional structures in pattern 125 in seam 120 are in the same co-planar device or metallization layer as the non-functional structures in pattern 125 in segment(s) 130 not in seam 120. For the example shown in FIG. 1B, functional unit 140A includes segments 130A (e.g., segments 130A1, 130A2). Segment 130A1 includes a first group of non-functional structures in pattern 125A in seam 120, and segment 130A2 includes a second group of the non-functional structures in the same pattern 125A in region 102. In the example of FIG. 1B, pattern 125A (in both segments 130A, e.g., in seam 120 and out) includes dummy features 124. Functional unit 140A is a circuit block of IC substrate 199 (e.g., an IC die) and includes first, second, and third sections 141A, 142A, 143A. Seam 120 (and segment 130A1) is between section 141A in region 101 and section 142A in region 102. Segment 130A2 is in region 102 and between sections 142A, 143A, also in region 102.

Multiple segments 130 may be placed within functional units 140 to allow for the placement of unit 140 in multiple positions in IC device 100 by aligning the appropriate segment 130 in seam 120. The placement of additional segments 130 within functional unit 140 enables additional placements of unit 140 in IC device 100, which provides design flexibility and enables increased LFU. The placement of segments 130 within functional units 140 determines the available positions of units 140 within IC device 100, e.g., with a pattern 125 in segment 130 aligned with the position of pattern 125 in seam 120. For example, functional unit 140A may be placed in IC device 100 with either of segment 130A1 or 130A2 aligned in seam 120. For the example (not shown) of segment 130A2 aligned in seam 120, functional unit 140A includes segment 130A2 with a group of non-functional structures in pattern 125A in seam 120 and segment 130A1 with a second group of the non-functional structures in the same pattern 125A in region 101. In such an embodiment (not shown), seam 120 (and segment 130A2) is between section 142A in region 101 and section 143A in region 102, and segment 130A1 is in region 101 and between sections 141A, 142A also in region 101.

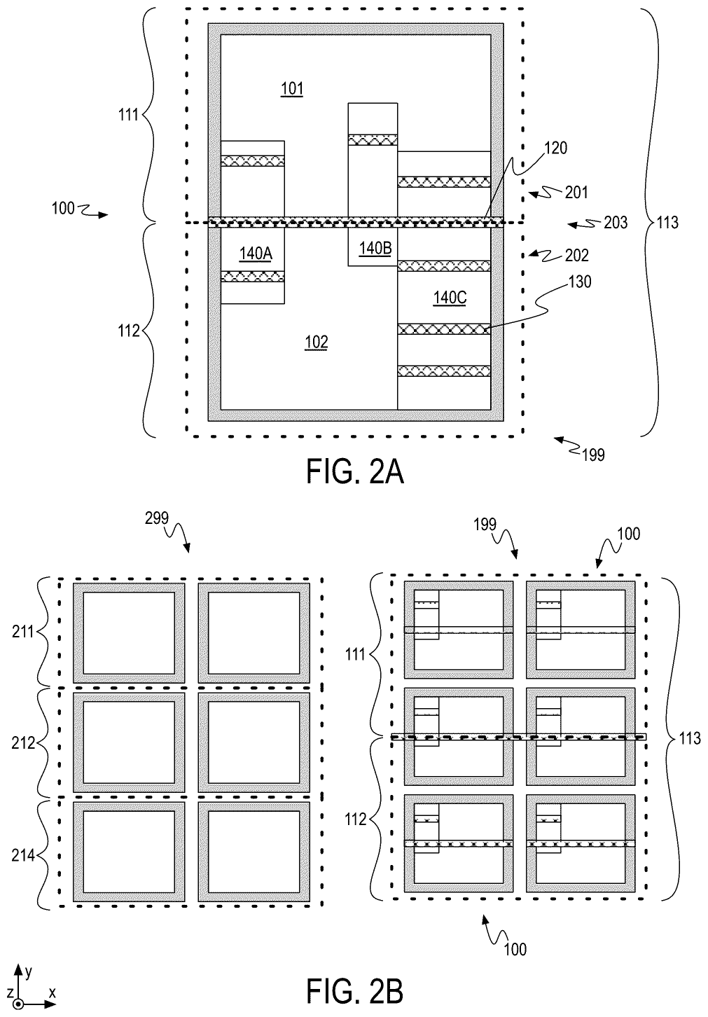

IC device 100 may include multiple, separate (e.g., different) functional units 140 utilizing multiple segments 130 per unit 140 to provide design and layout flexibility. In some embodiments, functional unit 140B is a second unit 140 in IC device 100 (along with unit 140A) with multiple segments 130B (e.g., segments 130B1, 130B2). Functional unit 140B includes segments 130B1, 130B2. Segment 130B1 includes a first group of non-functional structures (e.g., features 124) in pattern 125B in seam 120, and segment 130B2 includes a second group of the non-functional structures in the same pattern 125B in region 101. Functional unit 140B is a circuit block of IC substrate 199 and includes first, second, and third sections 141B, 142B, 143B. Seam 120 (and segment 130B1) is between section 142B in region 101 and section 143B in region 102. Segment 130B2 is in region 101 and between sections 141B, 142B, also in region 101. Segment 130B2 includes the same pattern 125B as segment 130B1 in seam 120. In some embodiments, functional units 140A, 140B include different patterns 125A, 125B. In some embodiments, pattern 125B is the same pattern (e.g., including the same non-functional structures in the same layout) as pattern 125A. In some embodiments, unit 140B is the same functional unit as unit 140A, but in another available placement in IC device 100. For example, in the embodiment of FIG. 2B, unit 140 may occupy one of at least four positions, e.g., with any one of segments 130A1, 130A2, 130B1, 130B2 aligned in seam 120.

Segments 130 may be placed in functional unit 140 to facilitate advantageous (e.g., simple and convenient for a design or layout of IC device 100) placement of unit 140 in IC device 100. For example, in at least some embodiments, as shown in FIG. 2B, unit 140 is rectangular with edges parallel to edges of IC device 100 and/or substrate 199, and segments 130 (e.g., in seam 120 and region(s) 101 and/or 102) are parallel with seam 120. Segments 130 may have a same length as a width of functional unit 140, which may be shorter than a length of seam 120 and width of IC device 100. For example, unit 140A has a width W_{A} equal to a length W_{A} of each of segments 130A1, 130A2 (e.g., all in the x-dimension). In some embodiments, IC device 100 has a width W₂ equal to a length W₂ of seam 120 (e.g., both in the x-dimension). In some embodiments, IC device 100 has a width W₃ equal to a length W₃ of seam 120 (e.g., both in the x-dimension). Widths and lengths W₂, W₃ are greater (e.g., wider or longer) than width and lengths W_{A}.

In contrast to functional units 140 able to be placed over and across seam 120, e.g., with segment 130 in and aligned with lithographic seam 120, functional units or circuit blocks incapable of spanning seam 120 would require functional units or blocks be separated (e.g., split up) and/or rearranged (requiring redesign resources) or IC device 100 be enlarged (wasting area). Circuit blocks or functional units 140 may already be designed to densely and efficiently layout circuit components into a minimum area, and any rearranging or other redesigning forced by incompatibility with a lithographic seam would likely fail to save area (or come at some other cost, such as degraded circuit or device performance). In adding segments 130 and providing a means for circuit blocks or units 140 to be placed over lithographic seam 120, the area of lithographic seam 120 (e.g., width in the y-dimension by length in the x-dimension) is small compared to the cost of such wasted space due to enlarging a device and die size. Rearranging or other redesigning of functional units to enable placement in IC device 100 impacts design ease of use and potential re-use of blocks. Wasted area (e.g., in an enlarged die, or between functional units not able to be conveniently placed) may require additional exposures for a same die count (e.g., due to adjacent lithographic fields having to overlap further due to nonlinear lithographic seams).

FIG. 1C shows various possible examples of non-functional structures (e.g., dummy features 124) in patterns 125 (e.g., patterns 125C-125G2). Yet other structures may be employed in patterns 125.

Patterns 125C, 125D include similar dummy features 124. Parallel dummy features 124 are oriented in the y-direction, aligned in rows that extend in the x-direction in patterns 125. Much as described at FIG. 1A, dummy features 124 may be smaller or larger to fill regions and provide feature density. Patterns 125C, 125D may be used to provide feature density in similar configurations, but dummy features 124 in pattern 125D are longer. Dummy features 124 in pattern 125C are shorter and have a gap along a centerline of pattern 125C that may allow for insertion of other inactive structures, whether lithographic assist features (such as features 121, 122, 123) or other structures (as will be described elsewhere herein).

Patterns 125E, 125F include similar dummy features 124. Parallel dummy features 124 are oriented in the x-direction, aligned in rows that also extend in the x-direction in patterns 125. The differing orientations (e.g., compared to patterns 125C, 125D) may be to match adjacent active features (e.g., adjacent a pattern 125 in a seam 120 or other segment 130). Much as smaller or larger dummy features 124 may be used to fill regions and provide feature density, more or fewer dummy features 124 may be used. For example, patterns 125E, 125F are similar, but pattern 125F includes more dummy features 124. The fewer dummy features 124 in pattern 125E leave a gap along a centerline of pattern 125E that may allow for insertion of other inactive structures.

Patterns 125G1, 125G2 include similar dummy features 124. Parallel dummy features 124 are oriented in the x-direction, aligned in rows that also extend in the x-direction in patterns 125. (Pattern 125G1 may be identical to pattern 125E.) Notably, pattern 125G2 includes dummy features 124 in pattern 125G1 with additional connections between adjacent features 124 to form continuous features 124. Either or both of discontinuous pattern 125G1 or discontinuous pattern 125G2 may be deployed in segments 130 or lithographic seam 120. In some embodiments, discontinuous pattern 125G1 is in one or more segments 130 in region 101 or 102 and a functional unit 140, and discontinuous pattern 125G1 is in lithographic seam 120 as part of a continuous pattern 125G2 (with added connections to make continuity).

FIGS. 2A and 2B illustrate plan views of IC substrates 199 with various lens field utilizations, both with IC devices 100 spanning multiple lithographic fields 111, 112, and with lithographic fields 111, 112 spanning multiple IC devices 100, in accordance with some embodiments. FIG. 2A shows an example substrate 199, e.g., an IC die, with a single IC device 100 utilizing multiple lithographic fields 111, 112. In some embodiments, substrate 199 is a wafer (or tile, etc.) and includes multiple IC dies. IC device includes regions 101, 102 separated by lithographic seam 120. IC device 100 has multiple functional units 140 straddling lithographic seam 120. Functional units 140 (e.g., units 140A, 140B, 140C) each have segments 130 that enable other placements of units 140 in IC device 100 and relative to seam 120. Large functional units 140 (e.g., unit 140C) may have more segments 130 to provide additional layout flexibility. Design control of functional units 140 may be provided to enable die splitting of layers into multiple fields (e.g., for high-NA lithography mask splitting) on product floor plans. Such layers having lithographic seam 120 may not be considered general global routing layers and instead functional features or structures may be maintained within functional units 140. As shown in FIG. 2A, some functional units 140 may have many segments 130 for optional aligning with, and placement in, lithographic seam 120. Such added segments 130 may be used for varied product configurations.

Region 101 is part of lithographic field 111, and region 102 is part of lithographic field 112. Lithographic field 113 includes fields 111, 112. As discussed, a photoresist layer is exposed with a single lithographic exposure using a corresponding reticle or mask to provide the pattern of lithographic field 111. The same photoresist layer is then exposed with a different lithographic exposure using a corresponding different reticle or mask to provide the pattern of lithographic field 112. Subsequent fabrication processing for the applicable layer (or layers) is then performed using the patterned photoresist as patterned with the two different fields and reticles. In regions 101, 102 (including functional units 140), co-planar layers that deploy lithographic seam 120 include functional features or structures, while lithographic seam 120 includes non-functional features or structures such as lithographic assist features, fill patterns, and so on.

As shown in FIG. 2A, lithographic field 111 may be patterned using a lithographic mask 201 and lithographic field 112 may be patterned using a lithographic mask 202. Lithographic masks 201, 202 may correspond to patterns from corresponding lithographic reticles (not shown), such as EUV reticles. Such masks further correspond to lithographic fields 111, 112 such that the masks 201, 202 provide the pattern being deployed in lithographic fields 111, 112. In some embodiments, lithographic fields 111, 112 are used for EUV lithographic exposures, for example, for lower device and/or metallization layers. In some embodiments, lithographic field 113 is used for non-EUV lithographic exposures, for example, for upper metallization layers, and with a pattern provided by a lithographic mask 203. Lithographic seam 120 enables the stitching together of multiple fields 111, 112 to pattern co-planar layers in a single device 100 spanning multiple reticle fields of multiple masks 201, 202. Segments 130 provide design and/or layout flexibility to efficiently use die and/or mask area when stitching together layers with multiple fields 111, 112.

FIG. 2B illustrates substrate 199 having multiple IC devices 100 with a lithographic seam between lithographic fields 111, 112 (and functional units with segments to enable multiple placements able to be aligned with seams). The compatibility of substrate 199 with seams enables the use of multiple lithographic exposures across single devices 100 and the capability of straddling IC devices 100 across seams between lithographic fields 111, 112. As shown, the employment of seams provides more efficient processing of substrate 199: for a given layer requiring a smaller (e.g., high-NA EUV) lithographic field, fewer exposures are needed to pattern IC devices 100. For example, two fields 111, 112 stitched together may be used to pattern IC devices 100 of substrate 199. More exposures of smaller fields 211, 212, 214 must be stitched together to pattern IC devices 100 of substrate 299.

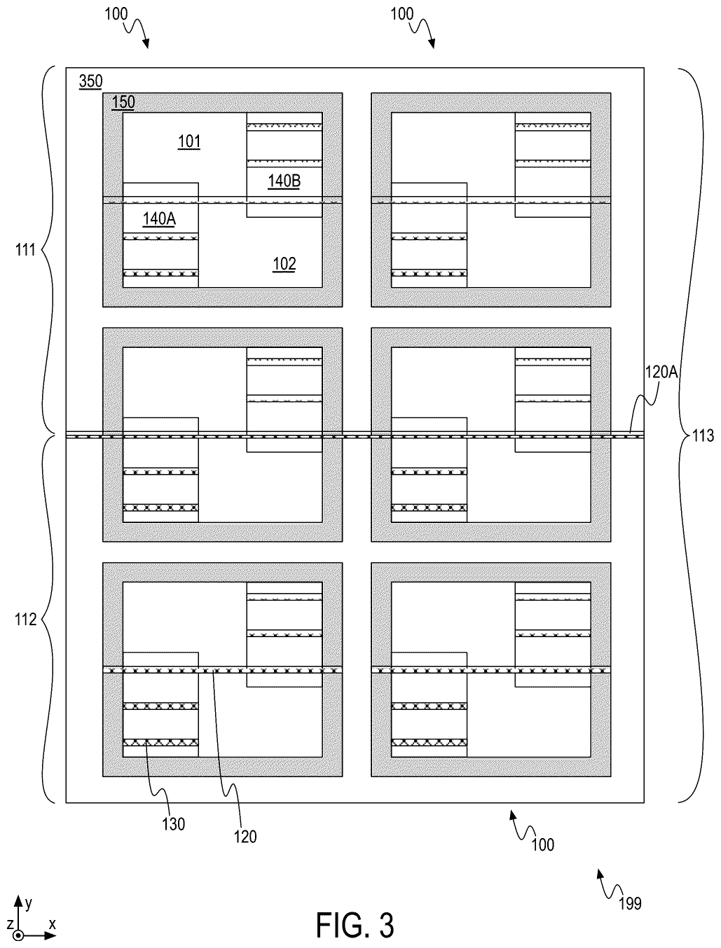

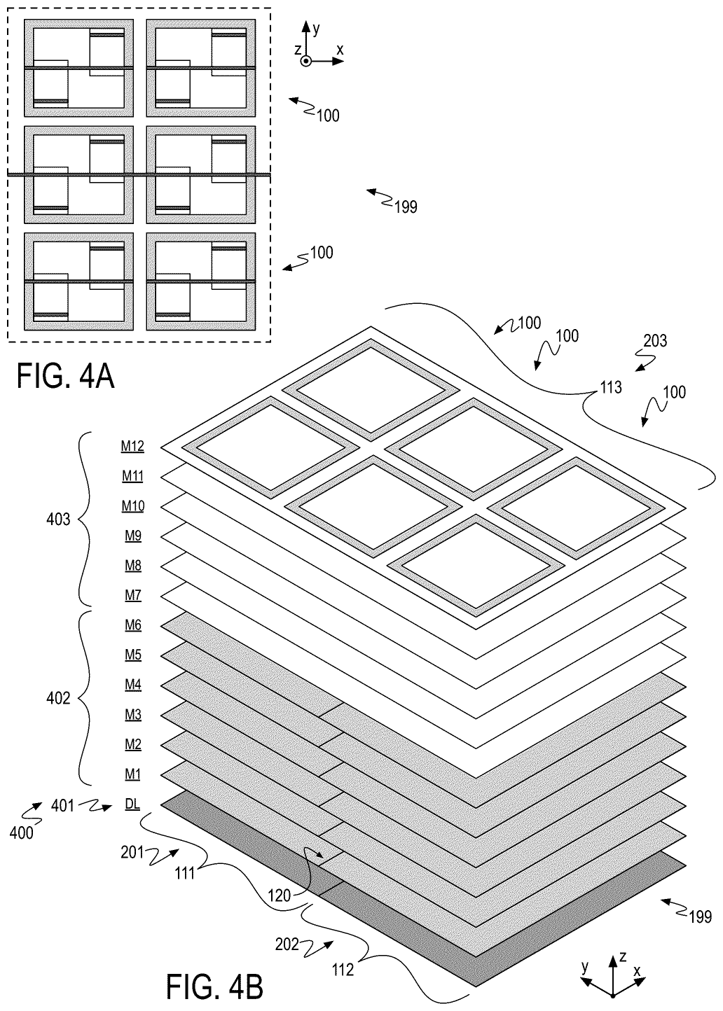

FIG. 3 illustrates a plan view of IC substrate 199 with IC devices 100 spanning multiple lithographic fields 111, 112, and with lithographic fields 111, 112 spanning multiple IC devices 100, in accordance with some embodiments. Substrate 199 is a wafer having multiple IC dies. Each IC device 100 of substrate 199 includes regions 101, 102 separated by seam 120. IC device 100 has multiple functional units 140 straddling seam 120. Functional units 140 (e.g., units 140A, 140B) each have segments 130 that enable other placements of units 140 relative to seam 120 in IC device 100.

Lithographic field 113 includes fields 111, 112. Each of lithographic fields 111, 112 covers multiple IC devices 100. Lithographic fields 111, 112 meet at lithographic seam 120A. Lithographic seam 120A differs from other seams 120 in the examples shown in FIG. 3. Other than lithographic seam 120A, seams 120 do not separate lithographic fields (e.g., fields 111, 112). IC devices 100 may have a standard layout to all be patterned together, but in the case of substrate 199 shown in FIG. 3, multiple IC devices 100 are in each field 111, 112 and some seams 120 are not at an overlap of lithographic fields (e.g., fields 111, 112). All seams 120 include non-functional structures, such as lithographic assist features 121, 122, 123, in a pattern repeated in segments 130, but lithographic seam 120A is where lithographic fields 111, 112 meet, including outside of IC devices 100 in substrate 199. Lithographic seam 120A extends beyond border region 150 and into a frame region 350 of substrate 199. As in IC devices 100, lithographic seam 120A includes a group of non-functional structures (such as lithographic assist features 121, 122, 123) in one or more co-planar device or metallization layers in frame region 350. In some embodiments, non-functional structures in lithographic seam 120A and frame region 350 are co-planar in the same device or metallization layer as in lithographic seam 120A in IC devices 100.

FIGS. 4A and 4B illustrate plan and isometric views of substrate 199 with IC devices 100 and co-planar device and metallization layers 401, 402 spanning multiple lithographic fields 111, 112, in accordance with some embodiments. FIG. 4A shows substrate 199 and IC devices 100 similar to, or the same as, substrate 199 and IC devices 100 described at FIG. 3 and below at FIG. 4B.

FIG. 4B illustrates a multilayer stack 400 of an example substrate 199, including multiple IC devices 100 having lower multi-lithographic field layers 401, 402 and upper layers 403 having a single lithographic field, in accordance with some implementations. In the example of FIG. 4B, a split-field device layer 401 (also labeled DL) or metallization layer 402 (lower layers M1 through M6) has fields 111, 112 separated by lithographic seams 120 such that fields 111 are defined by lithographic mask 201 and fields 112 are defined by lithographic mask 202, as discussed herein.

Furthermore, multilayer stack 400 illustrates that an upper metallization layer 403 above split-field device layer 401 and lower metallization layers 402 may not have split fields. For example, split-field device layer 401 or metallization layers 402 of substrate 199 is formed using two lithographic fields 111, 112, as discussed herein. In some embodiments, a co-planar device layer (e.g., layer 401, i.e., layer DL) and a co-planar metallization layer (e.g., layer M1 of layers 402) includes non-functional structures arrayed in the pattern in lithographic seams 120 and both layers (e.g., layers DL and M1) include active features in lithographic fields 111, 112. In some embodiments, lithographic fields 111, 112 include high-NA EUV lithographic fields. In contrast, layers 403 are fabricated using a single lithographic field 113 for the entirety of stack 400. In some embodiments, an upper co-planar metallization layer (e.g., layer M12 of layers 403) includes lithographic field 113, which includes lithographic fields 111, 112.

A split-field device or metallization layer may be deployed at any layer of substrate 199, such as one or more device layer(s) and one or more metallization layer(s). As discussed, a device layer is any layer used to fabricate an active device of substrate 199 and a metallization layer is a via or metal line layer of substrate 199 used to interconnect the active devices and/or provide routing to an external interface of substrate 199. In some embodiments, split-field device or metallization layer(s) is used at the lowest metallization layer or layers 402 of substrate 199, such as M1 and M2, for example. The techniques discussed herein, using lithographic seams (e.g., die mask zippers) allow other layers that have been optimized for the lens field utilization (LFU) and reticle area to be unchanged when patterned on tooling with a different optimization metric relative to those used for split-field device or metallization layers.

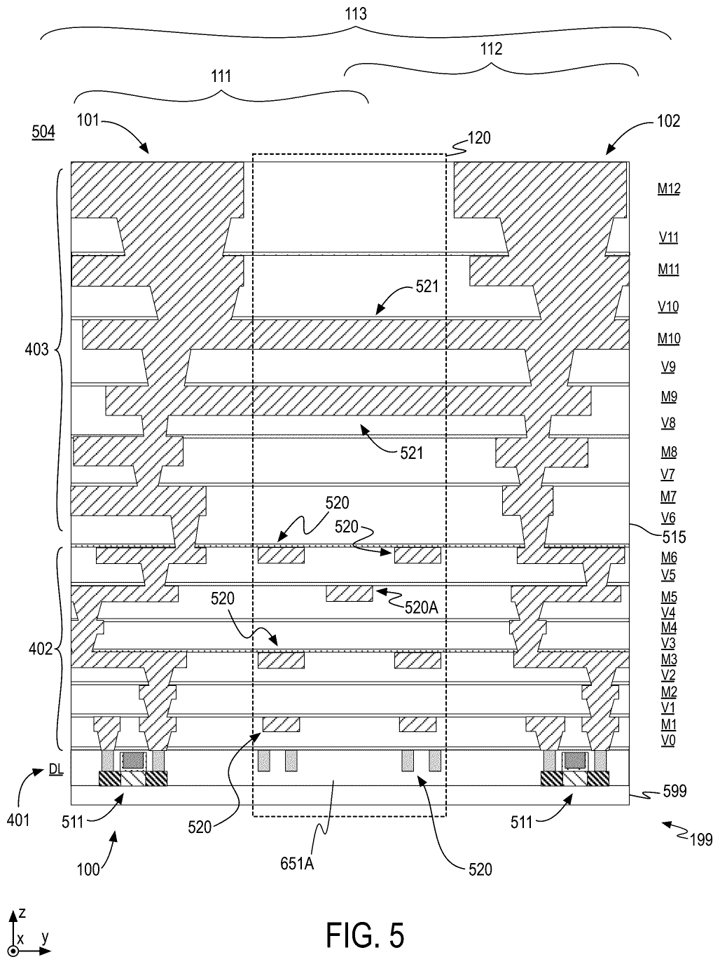

FIG. 5 illustrates a cross-sectional profile view of IC device 100 in substrate 199 having co-planar device and metallization layers 401, 402, 403 in regions 101, 102 on both sides of lithographic seam 120, in accordance with some embodiments. FIG. 5 provides a cross-sectional view of an exemplary portion 504 of IC device 100 taken across lithographic seam 120, in accordance with some implementations. For example, with reference to FIG. 1A, the cross-sectional view is taken in the y-dimension extending from region 101 to region 102 and across lithographic seam 120, looking in the positive x-direction. Notably, some layers of IC device 100 are fabricated using separate lithographic fields 111, 112 while others are fabricated using a lithographic field (e.g., field 113, as described at FIG. 2A) that encompasses the entirety of IC device 100.

As shown, IC device 100 includes a layer 599, having a lateral surface along the x-y plane. Layer 599 may be a base layer 599 of substrate 199. Layer 599 may be of any material known to be suitable for the fabrication of device circuitry. For example, layer 599 may include a semiconductor material, such as monocrystalline silicon (Si), germanium (Ge), silicon germanium (SiGe), a III-V material (e.g., gallium arsenide (GaAs)), a silicon carbide (SiC), or any combination thereof. In the illustrated example, planar transistors 511 are formed on and/or within layer 599 such that planar transistors 511 are part of a device layer 401. Device layer may include any active devices such as transistors (planar or multi-gate), memory devices, capacitors, resistors, optoelectronic devices, or switches.

Interconnection of transistors 511, routing to an outside device (not shown), routing within IC device 100, routing through IC device 100, etc., is provided by metallization layers 402, 403. Transistors 511 and metallization layers 402, 403 are embedded within dielectric materials 515. Metallization layers 402, 403 include lower-level metallization layers 402 and higher-level metallization layers 403. In the illustrated example, lower-level metallization layers 402 include V0-M6 and higher-level metallization layers 403 include V6-M12, however any such metallization layers may be deployed. In some embodiments, lower level metallization layers 402 are subject to field splitting while higher level metallization layers 403 are not. However, any combination of field splitting layers may be used.

As shown, for those layers using field splitting, non-functional structures 520 (such as lithographic assist features 121, 122, 123) may be deployed in lithographic seam 120. In some embodiments, most of non-functional structures 520 in seam 120 are dummy features 124 (e.g. on both sides of seam 120), and one or more non-functional structures 520A are lithographic assist features (such as features 121, 122, 123). Such non-functional structures 520 are illustrated in layers DL, M1, M3, M6, M7, but they may be used in any of device layer 401, lower-level metallization layers 402, and higher-level metallization layers 403. Furthermore, in layers where a single lithographic field encompasses IC device 100, metallization lines 521 (or other functional structures or features) may be provided in the area of those layers used for lithographic seam 120. For example, in such layers, lithographic seam 120 may deploy active features.

Each of device layer 401, lower-level metallization layers 402, and higher-level metallization layers 403 are co-planar as discussed herein. IC device 100 includes a co-planar device layer 401 and co-planar metallization layers 402, 403 such that one or more of co-planar device layer 401 and/or co-planar metallization layers 402, 403 include non-functional structures 520 (e.g., DL, M1, M3, M6, M7, or others). The one or more of co-planar device layer 401 and/or co-planar metallization layers 402, 403 including non-functional structures 520 also include active features of regions 101, 102. As discussed, other co-planar layers of IC device 100 other than the one or more of co-planar device layer 401 and/or co-planar metallization layers 402, 403 including non-functional structures 520 may be fabricated using a lithographic field that encompasses the entirety of IC device 100. In some embodiments, a second co-planar metallization layers 402, 403 (e.g., layer M9, M10, or others) includes an active metal line such as one of metallization lines 521 extending over lithographic seam 120 and between regions 101, 102. Such metal lines may be allowed or disallowed in the design of an IC die.

Though not shown in FIG. 5, IC device 100 may include other metallization layers, for example, on a backside of layer 599, opposite upper metallization layers. Such backside layers may be like any of the other layers described herein. In many embodiments, backside layers are large metallization layers (e.g., with interconnect structures at least as large as in layer M12). In some such embodiments, backside layers are patterned with a single exposure of lithographic field 113.

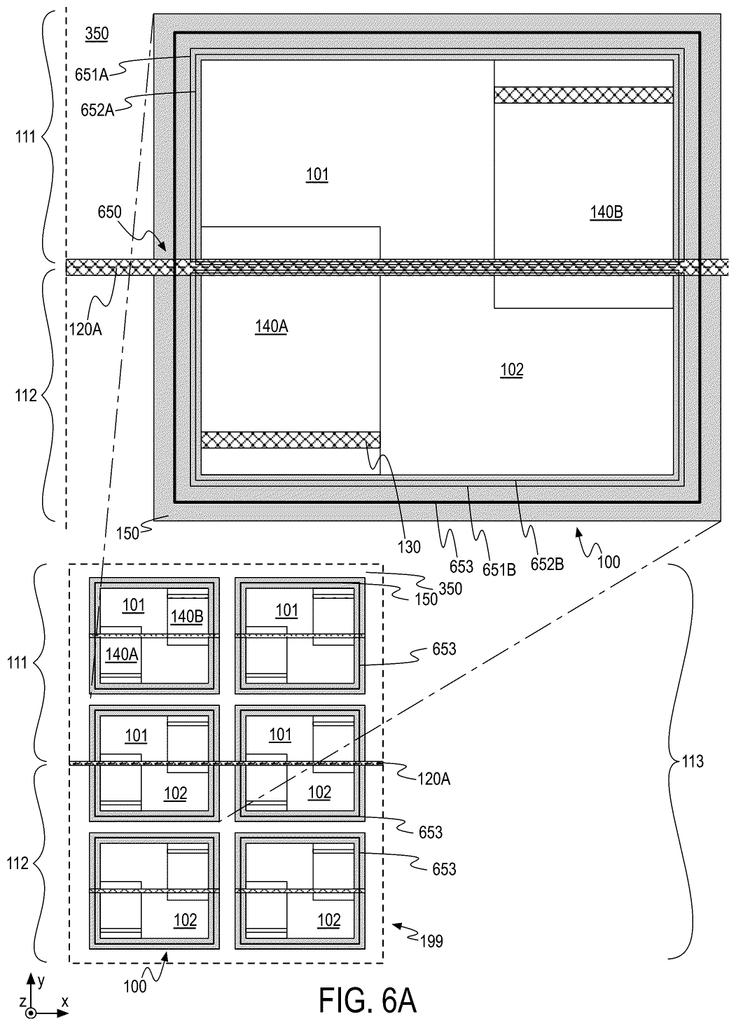

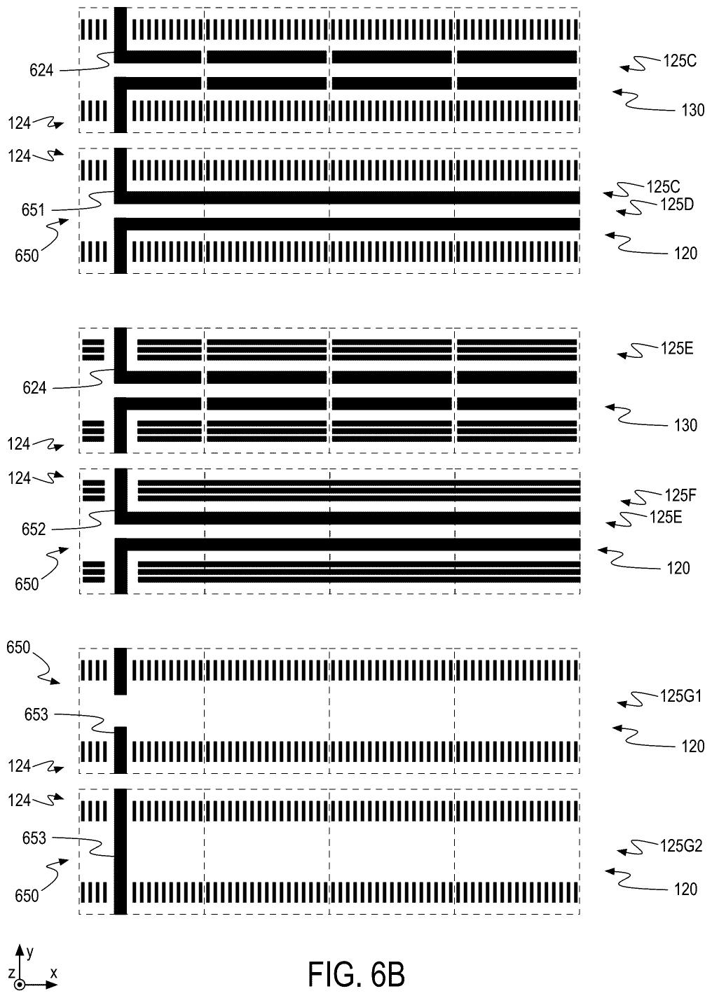

FIGS. 6A and 6B illustrate plan views of etch rings 651, 652 and guard rings 653 around active regions 101, 102 of IC devices 100, including in and through lithographic seam 120, in accordance with some embodiments. FIG. 6A shows substrate 199 and IC devices 100 similar to, or the same as, substrate 199 and IC devices 100 described at FIG. 3. Notably, as shown in FIG. 6A, IC devices 100 may include guard rings 653 in inactive border regions 150 of IC devices 100. Co-planar metallization layers (e.g., layer 402, 403 as described at FIG. 4B or 5) include active structures in regions 101, 102. Guard ring 653 is around the active structures in regions 101, 102. Guard ring 653 is between inactive frame region 350 and the active structures in regions 101, 102. Notably, in each IC device 100, a single guard ring 653 is around both of regions 101, 102 (although double guard rings 653 around both of regions 101, 102 are possible).

Guard ring 653 may be any suitable structure. In many embodiments, guard rings 653 around IC devices 100 are metallization features. In some such embodiments, guard rings 653 are continuous non-functional walls through substrate 199. For example, guard rings 653 may form hermetic barriers laterally around active regions 101, 102 of IC devices 100, e.g., to protect active structures from moisture, etc. Guard rings 653 may be through-substrate guard rings 653 that extend through all (e.g., upper and lower) metallization layers and a device layer (and any thickness of semiconductor material in substrate 199). In embodiments with backside layers, guard rings 653 may extend through backside layers as well. In some embodiments, guard rings 653 are non-functional walls only partially through substrate 199, e.g., on only a frontside or backside, and/or only through some layers (but not all) of substrate 199.

FIG. 6A also shows a magnified IC device 100 with lithographic seam 120A extending beyond guard ring 653 and into frame region 350. Lithographic seam 120A includes a group of non-functional structures (such as features 121, 122, 123, 124), for example, in a lower co-planar device or metallization layer (e.g., layer 401 or 402 as described at FIG. 4B or 5) in frame region 350. Some IC devices 100 (e.g., in a middle row) of substrate 199 are in, and at the meeting of, lithographic fields 111, 112, with lithographic seam 120A extending through IC devices 100 and into frame region 350. Other, adjacent IC devices 100 (e.g., in only one of lithographic fields 111, 112) include lithographic seam 120 that does not extend into frame region 350 or beyond guard rings 653. In some embodiments, guard rings 653 are discontinuous non-functional walls through substrate 199, for example, with discontinuities or interruptions at areas 650, where border region 150 and seam 120A meet or cross.

In some embodiments, IC devices 100 include one or both of etch rings 651, 652. Etch rings 651, 652 may protect regions 101, 102, e.g., prior to and during the formation of guard ring 653. In some embodiments, etch rings 651, 652 are inactive structures, e.g., non-functional walls, continuous or discontinuous, that run through seam 120. In some embodiments, etch rings 651 run through regions 101, 102, on both sides of seam 120, and seam 120 runs between etch rings 651. In some embodiments, etch rings 651 are inactive structures, e.g., non-functional walls, that run between seam 120 and the active structures of regions 101, 102.

Etch rings 651 are in the co-planar device or metallization layers patterned using split lithographic fields 111, 112. In some embodiments, etch rings 651 are in device or lower metallization layers. A separate etch ring 651A is in lithographic field 111, and etch ring 651B is in lithographic field 112. In many embodiments, etch rings 651A, 651B are non-functional walls between the active structures of regions 101, 102 and in seam 120. In some embodiments, etch rings 651A, 651B include a double set of walls between the active structures of regions 101, 102.

In some embodiments, an etch ring 652 is between etch rings 651A, 651B and regions 101 or 102. Etch ring 652 may be a non-functional wall broken (e.g., interrupted or discontinuous) at seam 120. A separate etch ring 652A (or portion of etch ring 652) is around region 101, and etch ring 652B (or portion of etch ring 652) is around region 102. Although rings 651, 652 are shown somewhat offset in FIG. 6A, in some embodiments, rings 651, 652 are substantially aligned. In the example of FIG. 6A, a ring 651 (e.g., ring 651A or 651B) is between a corresponding ring 652 (e.g., ring 652A or 652B) and region 101 or 102 within seam 120, and a ring 652 (e.g., ring 652A or 652B) is between a corresponding ring 651 (e.g., ring 651A or 651B) and region 101 or 102 outside of seam 120. The opposite (or other configurations) may also be true in other embodiments. In some embodiments, etch rings 651 are surrounded by etch rings 652. In other embodiments, etch rings 652 are surrounded by etch rings 651.

FIG. 6B shows various possible examples of non-functional structures (e.g., dummy features 124) in patterns 125 (e.g., patterns 125C-125G2), including at intersection areas 650 with etch and guard rings 651, 652, 653. Yet other structures may be employed in patterns 125.

Patterns 125C, 125D include similar dummy features 124. In some embodiments, patterns 125C, 125D are identical except for additions made by a layout or mask prep group, e.g., to make a discontinuous dummy (or placeholder) pattern 125C into a continuous pattern 125D. Pattern 125D in seam 120 includes portions of etch rings 651 or 652 adjacent area 650, where seam 120 intersects border region. Pattern 125C includes similar dummy etch ring portion(s) 624. In some embodiments, pattern 125C is in a segment 130 outside of lithographic seam 120, and pattern 125D is in seam 120. Pattern 125D includes pattern 125C as well as additional connections, which make continuous those portions of etch rings 651 in pattern 125D. Patterns 125C, 125D may be used in both segments 130 and seam 120. In some embodiments, discontinuous pattern 125C is in a segment 130 outside of lithographic seam 120, and continuous pattern 125D is in seam 120. In some such embodiments, discontinuous pattern 125C outside of lithographic seam 120 is drawn by design, and a layout or mask prep group makes connections between features to convert pattern 125C in seam 120 into continuous pattern 125D as part of etch rings 651 or 652. In some embodiments, discontinuous pattern 125C is drawn by design in seam 120 and in segment 130 outside of seam 120 to include only dummy features 124, and a layout or mask prep group adds discontinuous or continuous portions of etch rings 651 or 652 to convert pattern 125C in seam 120 into continuous pattern 125D as part of etch rings 651 or 652. In some embodiments, pattern 125D in seam 120 includes portions of etch rings 651 in metallization layers 402 and portions of etch rings 652 in metallization layers 403. In some embodiments, discontinuities in pattern 125D in seam 120 (e.g., discontinuities in etch rings 652) allow for metallization lines 521 to cross seam 120.

Patterns 125E, 125F include similar dummy features 124. In some embodiments, patterns 125E, 125F are identical except for additions made by a layout or mask prep group, e.g., to make a discontinuous dummy (or placeholder) pattern 125E into a continuous pattern 125F. Pattern 125F in seam 120 includes portions of etch rings 651 or 652 adjacent area 650, where seam 120 intersects border region. Pattern 125E includes similar dummy etch ring portion(s) 624. In some embodiments, pattern 125E is in a segment 130 outside of lithographic seam 120, and pattern 125F is in seam 120. Pattern 125F includes pattern 125E as well as additional connections, which make continuous those portions of etch rings 652 in pattern 125F. Patterns 125E, 125F may be used in both segments 130 and seam 120. In some embodiments, discontinuous pattern 125E is in a segment 130 outside of lithographic seam 120, and continuous pattern 125F is in seam 120. In some such embodiments, discontinuous pattern 125E outside of lithographic seam 120 is drawn by design, and a layout or mask prep group connections to convert pattern 125E in seam 120 into continuous pattern 125F as part of etch rings 651 or 652. In some embodiments, discontinuous pattern 125E is drawn by design in seam 120 and in segment 130 outside of seam 120 to include only dummy features 124, and a layout or mask prep group adds discontinuous or continuous portions of etch rings 651 or 652 to convert pattern 125E in seam 120 into continuous pattern 125F as part of etch rings 651 or 652. In some embodiments, pattern 125F in seam 120 includes portions of etch rings 651 in metallization layers 402 and portions of etch rings 652 in metallization layers 403.

Patterns 125G1, 125G2 include similar dummy features 124 in seam 120 adjacent area 650, where seam 120 intersects the border region. In some embodiments, as shown in pattern 125G1, guard ring 653 is discontinuous at area 650 and seam 120. Breaks in guard ring 653 may allow for a continuous lithographic seam 120, e.g., to continue into border and frame regions 150, 350 (as described at FIG. 6A). In some embodiments, as shown in pattern 125G1, guard ring 653 is discontinuous at area 650 and seam 120. Breaks in guard ring 653 may allow for a continuous lithographic seam 120, e.g., to continue into border and frame regions 150, 350 (as described at FIG. 6A), without interruption of non-active structures and features in seam 120. In some embodiments, as shown in pattern 125G2, guard ring 653 is continuous at area 650 and seam 120. A continuous guard ring 653 may enable protection, e.g., by a hermetic seal around regions 101, 102 of device 100.

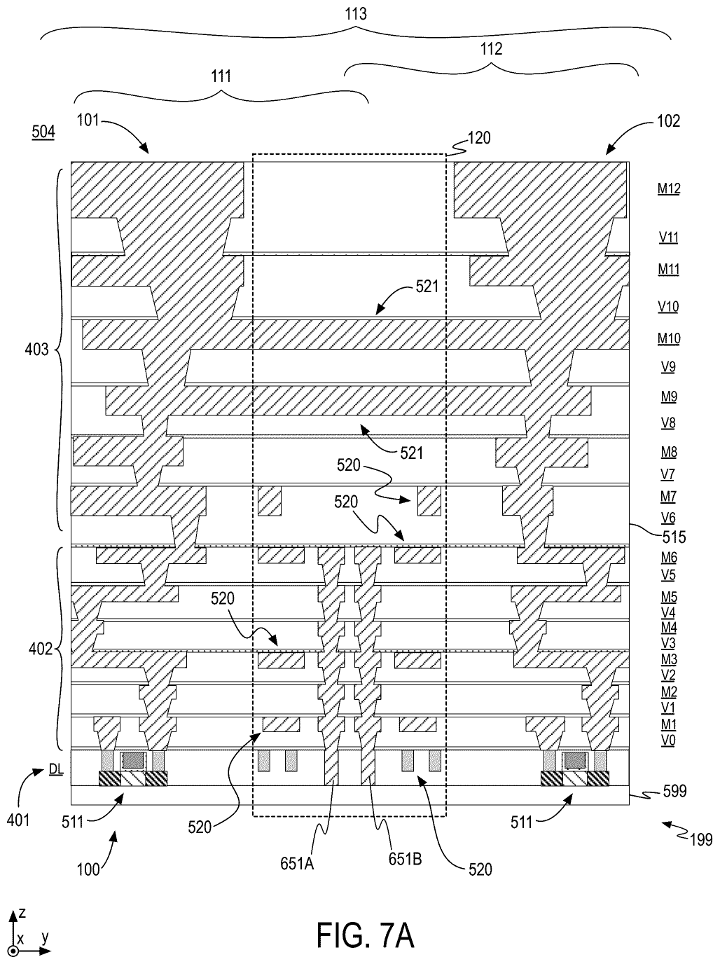

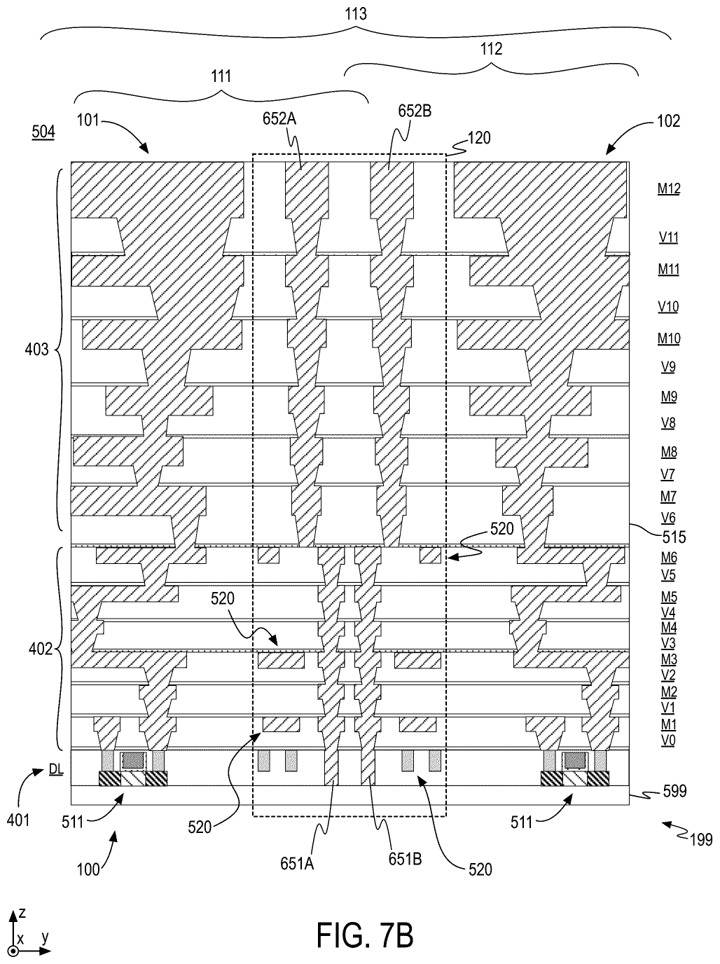

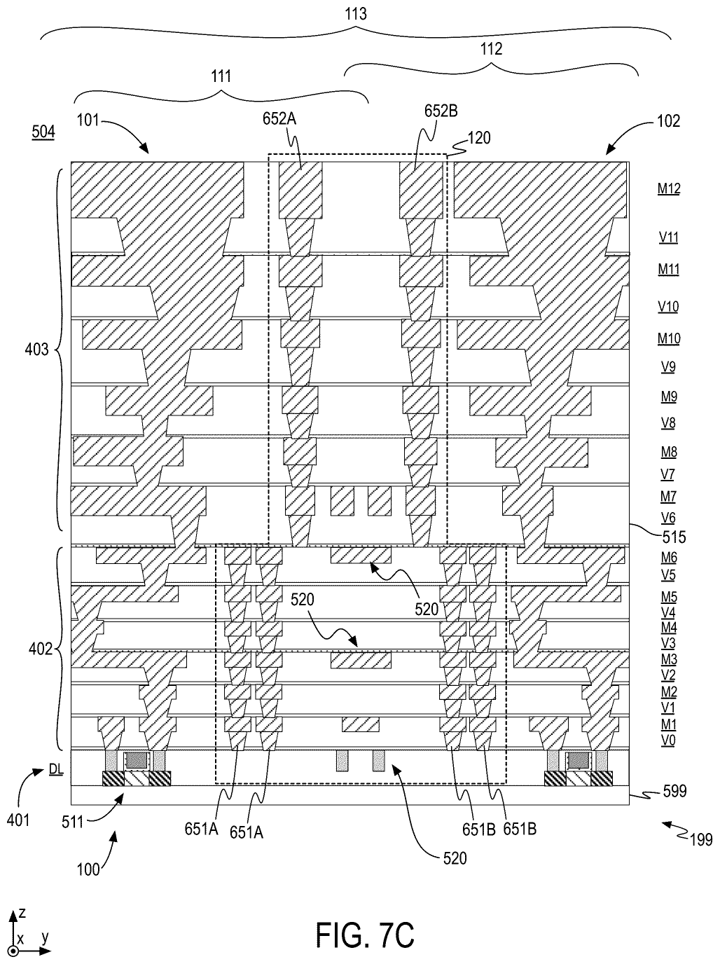

FIGS. 7A, 7B, and 7C illustrate cross-sectional profile views of IC device 100 in substrate 199 having co-planar device and metallization layers 401, 402, 403, including etch rings 651, 652 in lithographic seam 120, in accordance with some embodiments. IC device 100 is much as described at FIG. 5. Notably, IC device 100 may include either or both (or neither) of etch rings 651, 652 in lithographic seam 120.

FIG. 7A shows co-planar device and metallization layers 401, 402 with active structures in regions 101, 102 and non-functional walls of rings 651 in layers 401. The non-functional walls of rings 651A, 651B are in seam 120. The non-functional wall of ring 651A is between the active structures of region 101 and the non-functional wall of ring 651B. The non-functional wall of ring 651B is between the active structures of region 102 and the non-functional wall of ring 651A. Rings 651 may be continuous or discontinuous around regions 101, 102. Continuous rings 651 may provide increased protection of structures in regions 101, 102. Discontinuous rings 651 may allow space for structures in seam 120 (including but not limited to features 121, 122, 123, 124).

As shown, for those layers using field splitting, non-functional structures 520 (such as inactive features 121, 122, 123, 124) may be deployed in lithographic seam 120. Such non-functional structures 520 may be used in any of device layer 401, lower-level metallization layers 402, and higher-level metallization layers 403. In some embodiments, non-functional structures 520 are between ring 651A and region 101 and between 651B and region 102. In some embodiments, non-functional structures 520 are between rings 651A, 651B. Metallization lines 521 are active metal lines 521 in layer M9, M10 of layers 403 and extend over lithographic seam 120, between regions 101, 102.

FIG. 7B shows co-planar device and metallization layers 401, 402 with active structures in regions 101, 102 and non-functional walls of rings 651, 652 in layers 401, 402. The non-functional walls of rings 651, 652 are in seam 120. The non-functional walls of rings 651A, 652A are between the active structures of region 101 and the non-functional walls of rings 651B, 652B. The non-functional walls of rings 651B, 652B are between the active structures of region 102 and the non-functional walls of rings 651A, 652A. Rings 651, 652 may be continuous or discontinuous around regions 101, 102. Continuous rings 651, 652 may provide increased protection of structures in regions 101, 102. Discontinuous rings 651, 652 may allow space for structures in seam 120 (including but not limited to features 121, 122, 123, 124 and lines 521). Rings 651, 652 are offset in the example of FIG. 7B (e.g., with rings 651 spaced more narrowly than rings 652). In some embodiments, rings 651, 652 are vertically aligned.

FIG. 7C shows co-planar device and metallization layers 401, 402 with active structures in regions 101, 102 and non-functional walls of rings 651, 652 in layers 401, 402. Notably, the example of FIG. 7C includes double walls of rings 651 in seam 120. In some embodiments, device 100 includes double walls of rings 652 in seam 120. Notably, rings 651, 652 are offset in the example of FIG. 7C (e.g., with rings 652 spaced more narrowly than rings 651).

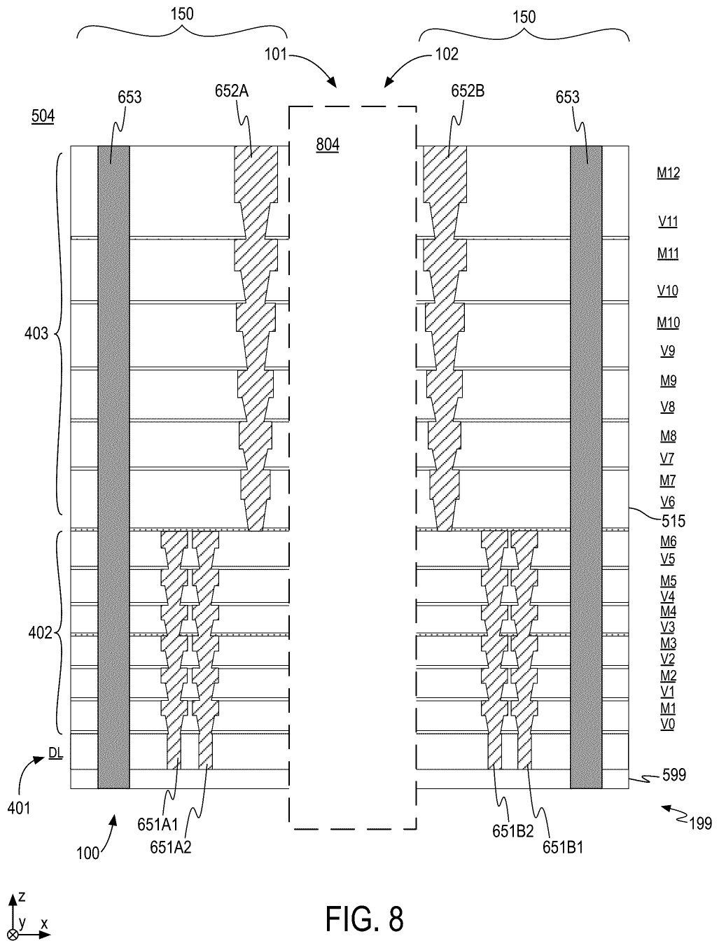

FIG. 8 illustrates a cross-sectional profile view of IC device 100 in substrate 199 having co-planar device and metallization layers 401, 402, 403, including etch rings 651, 652 and guard ring 653, in accordance with some embodiments. FIG. 8 provides a cross-sectional view of IC device 100, including portion 804, which includes regions 101, 102, between etch rings 651, 652 and guard ring 653, in accordance with some implementations. For example, with reference to FIG. 6, the cross-sectional view is taken in the x-dimension across region 101 or 102 and to one side or the other of lithographic seam 120, looking in the positive y-direction. FIG. 8 highlights the structures and relative orientations of etch rings 651, 652 and guard ring 653 in border region 150. Notably, the details of the lithographic seam region are not shown in FIG. 8.

Co-planar device and metallization layers 401, 402 include the non-functional walls of etch rings 651. Co-planar metallization layers 403 include the non-functional walls of etch rings 652. Border region 150 is around regions 101, 102 (in portion 804). Guard ring 653 is in border region 150 and around regions 101, 102. The non-functional walls of etch rings 651 are between the non-functional wall of guard ring 653 and regions 101, 102. The non-functional walls of etch rings 652 (in layers 403) are between the non-functional walls of etch rings 651 (in layers 401, 402) and regions 101, 102.

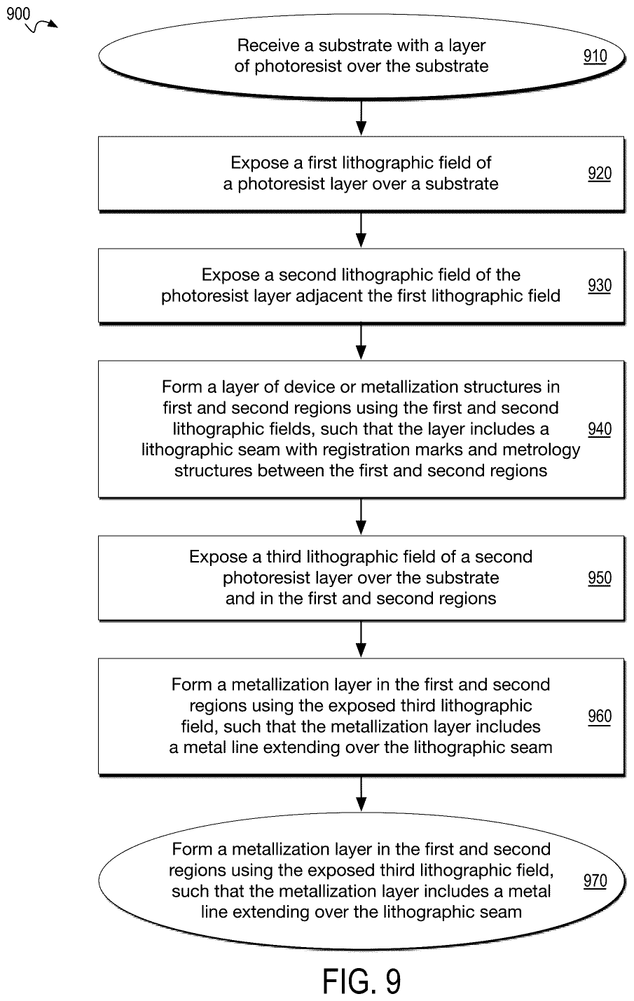

FIG. 9 is a flow chart of methods or a process 900 for forming an IC device having a lithographic seam in one or more layers thereof, in accordance with some embodiments. For example, process 900 may be implemented to fabricate any IC substrate (such as an IC die) or device structures discussed herein. Process 900 include operations 910-970. Some operations shown in FIG. 9 are optional. Additional operations may be included. FIG. 9 shows an example sequence, but the operations can be done in other orders as well, and some operations may be omitted. Some operations can also be performed multiple times before other operations are performed. For example, multiple lithographic fields may be exposed. Some operations may be included within other operations so that the number of operations illustrated FIG. 9 is not a limitation of the process 900.

Process 900 begins at operation 910, where a wafer coated in photoresist is received for processing. The wafer may include any suitable substrate material. For example, the substrate may include a semiconductor material such as monocrystalline silicon (Si), germanium (Ge), silicon germanium (SiGe), a III-V material (e.g., gallium arsenide (GaAs)), a silicon carbide (SiC), or any combination thereof. The substrate may include an insulator material, including crystalline materials, such as a sapphire (Al₂O₃). The received wafer may be partially fabricated to include a portion of a device layer already formed or an entirety of a device layer and metallization layers already formed. For example, the received wafer may be received for device layer processing, metal line layer processing, via layer processing, and so on such that the pertinent layer being fabricated is to be fabricated with die splitting into multiple lithographic fields. The device layer being fabricated or previously fabricated may include transistors, memory devices, capacitors, resistors, optoelectronic devices, switches, or any other active or passive electronic devices, or portions thereof. The metallization layer(s) may include via layers and metal line layers to interconnect and provide access to the devices. The wafer is coated with a photoresist layer for patterning operations such that the photoresist layer may include any suitable photoresist material.

Processing continues at operation 920, where a first lithographic field of the substrate is exposed using a first lithographic mask. For example, the first lithographic field corresponds to a split field of a monolithic IC die to be segmented from the wafer. For example, process 900 includes exposing a first lithographic field of a photoresist layer over a die. In some embodiments, the exposure at operation 920 is a high numerical aperture extreme ultraviolet exposure. In some embodiments, the first exposure is performed to provide a lithographic field as discussed with respect to FIGS. 3 and 4. Such patterning of the first lithographic field provides active features or structures for functional units of the first lithographic field. In some embodiments, functional units of the first lithographic field are rectangular functional units.

Processing continues at operation 930, where a second lithographic field of the substrate is exposed using a second lithographic mask such that the second lithographic field is immediately adjacent the first lithographic field. For example, the second lithographic field corresponds to a second split field of the monolithic IC die to be segmented from the wafer. For example, process 900 includes exposing a second lithographic field of the photoresist layer over the die. In some embodiments, the exposure at operation 920 is a high numerical aperture extreme ultraviolet exposure. In some embodiments, the first exposure is performed to provide a lithographic field as discussed with respect to FIGS. 3 and 4. Such patterning of the second lithographic field provides active features or structures for functional units of the second lithographic field. In some embodiments, functional units of the second lithographic field are rectangular functional units.

As discussed, such patterned first and second lithographic fields pattern a lithographic seam (e.g., die mask zipper) at the overlap between the patterned fields. The overlap may be any suitable distance such as distance not less than a maximum distance across the lithographic seam. The overlap and the lithographic seam may be rectilinear, e.g., linear, which may favorably align with desired die fields. Such patterning of the lithographic seam patterns non-functional features or structures inclusive of lithographic registration marks and metrology structures. In some embodiments, a pattern of non-functional features or structures in the lithographic seam is also in one or both of the first and second lithographic fields, e.g., in segments having a same width as the lithographic seam and a length equal to a parallel dimension of a functional unit or block, the segment parallel to the lithographic seam. In some embodiments, a functional unit or block will include multiple segments having the pattern of non-functional features or structures also in the lithographic seam. Such segment(s) may be inserted in a functional unit or block to enable multiple placement options for the functional unit or block in an IC die.

Such processing operations may be performed any number of times to pattern the photoresist layer over the die. In some embodiments, two lithographic fields are used; however, any number of lithographic fields per die may be deployed such as 3, 4, 6, or 8 fields per die.

Processing continues at operation 940 where a layer of one of device structures or metallization structures are formed in first and second regions of the die using the exposed first and second lithographic fields of the photoresist layer. For example, the layer (e.g., a device material layer, a via metallization layer, a metal line metallization layer, etc.) is fabricated using the patterned photoresist layer such that the fabricated regions correspond to the exposed first and second lithographic fields. In some embodiments, the layer includes one or more (e.g., rectangular) functional units of the device structures or metallization structures, and the one or more functional unit(s) have a first portion in the first region and a second portion in the second region. Furthermore, the layer further includes a lithographic seam between the first and second regions such that the lithographic seam includes non-functional features of lithographic registration marks and/or metrology structures patterned during the exposure of the first or second lithographic fields. In some embodiments, the one or more functional unit(s) span over or across the lithographic seam. Any layer of an IC die, such as a device layer or metallization layer (refer to FIG. 5), may be fabricated using operations 920-940.

Processing continues at operation 950, where lithography exposure is performed for another layer of the IC die being fabricated. For example, after additional processing a second photoresist layer is provided over the wafer including the IC die being fabricated. At operation 950, the exposure encompasses the first and second lithographic fields exposed at operations 920, 930 and, optionally encompasses the entirety of the IC die to be segmented from the wafer. For example, the lithographic exposure at operation 950 exposes a third lithographic field of a second photoresist layer over the die such that the third lithographic field includes the areas of the first and second lithographic fields patterned at operations 920, 930, respectively.

Processing continues at operation 960, where a higher layer of the IC die is fabricated. In the illustrated example, the higher layer is a metallization layer having a metal line that extends over the lithographic seam formed at operation 940. For example, a metallization layer having a metal line (refer to FIG. 5) that extends over the lithographic seam may be formed using metallization techniques such as transferring the pattern of the patterned photoresist to an underlying dielectric layer and performing metal fill and optional planarization. In other examples, the fabrication at operation 960 provides any device or metallization layer having a larger lithographic field size than the patterning at operations 920, 930. Furthermore, although discussed with respect to such patterning being for a higher layer in the IC die, such techniques may be deployed at lower levels or both lower and higher levels in the fabrication stack.

Processing continues at operation 970, where an integrated circuit device including a lithographic seam is output. For example, a die including multiple lithographic fields in one or more lithographic seam layers (and single fields in other layers) may be singulated from a remainder of the substrate (i.e., substrate wafer), packaged, and so on, and eventually included in an electronic device. In some embodiments, adjacent dies may include different lithographic fields. In some embodiments, a first die is within a first lithographic field, a second die is within an adjacent second lithographic field, and a third die is within an area of a third lithographic field that overlaps with the first and second lithographic fields. In some such embodiments, a lithographic seam between first and second lithographic fields crosses the third die (e.g., even though the first and second dies were completely within either the first or second lithographic field.

Exemplary devices and systems are discussed herein below. In some embodiments, a system includes a first die including memory circuitry, a second die including logic circuitry, and a power supply coupled to the first and/or second dies, the first or second die including first functional units in a first region of the first or second die, second functional units in a second region of the first or second die such that the first and second functional units include co-planar device layer and a number of co-planar metallization layers, and a lithographic seam between the first and second functional units. Such functional units and the lithographic seam may have any characteristics discussed herein.

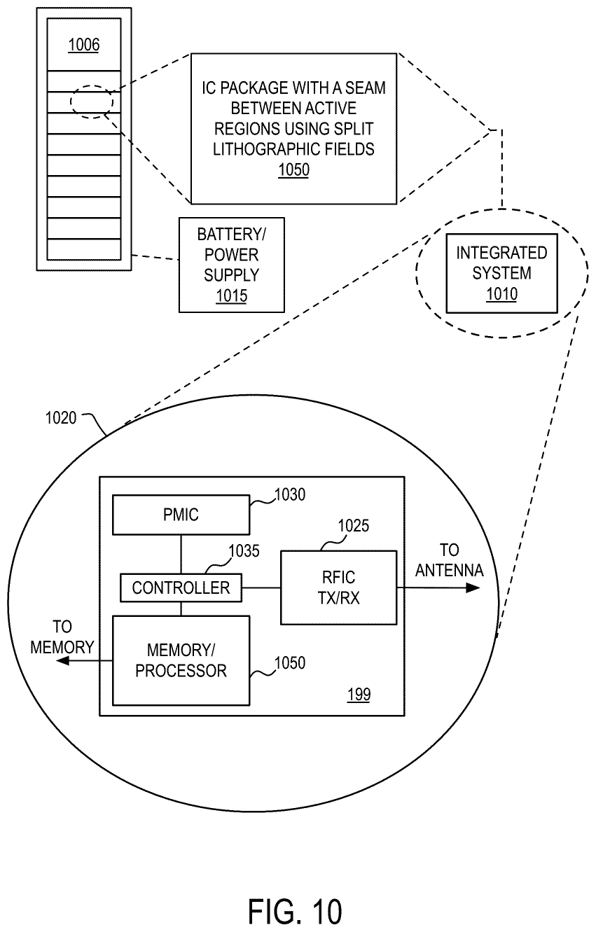

FIG. 10 illustrates a diagram of an example data server machine 1006 employing an IC device having a seam between active regions using split lithographic fields, in accordance with some embodiments. Server machine 1006 may be any commercial server, for example, including any number of high-performance computing platforms disposed within a rack and networked together for electronic data processing, which in the exemplary embodiment includes one or more devices 1050 with a seam between active regions using split lithographic fields.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 1050 is a microprocessor including a static RAM (SRAM) cache memory. As shown, device 1050 may be an IC device having a seam between active regions in split lithographic fields, as discussed herein. Device 1050 may be further coupled to (e.g., communicatively coupled to) a board, an interposer, or a substrate 199 along with, one or more of a power management IC (PMIC) 1030, RF (wireless) IC (RFIC) 1025 including a wideband RF (wireless) transmitter and/or receiver (TX/RX) (e.g., including a digital baseband and an analog front end module further includes a power amplifier on a transmit path and a low noise amplifier on a receive path), and a controller 1035 thereof. In some embodiments, RFIC 1025, PMIC 1030, controller 1035, and device 1050 include a seam between active regions of split lithographic fields.

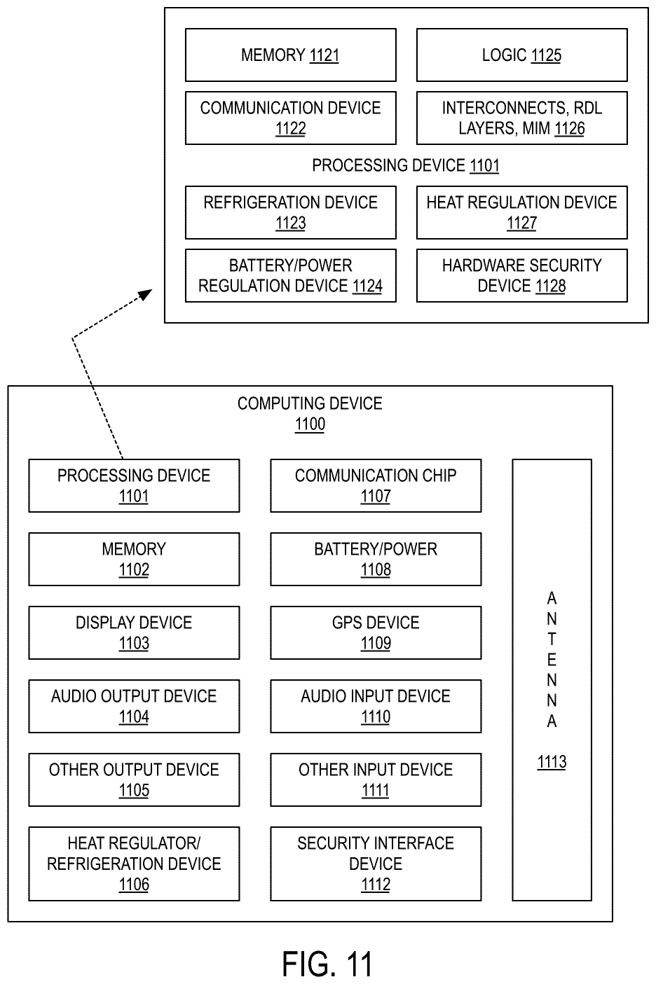

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-MRAM).

Computing device 1100 may include a heat regulation/refrigeration device 1106. Heat regulation/refrigeration device 1106 may maintain processing device 1101 (and/or other components of computing device 1100) at a predetermined low temperature during operation.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes first and second regions of an integrated circuit (IC) die and a seam therebetween, wherein the first and second regions include co-planar device layers and a plurality of co-planar metallization layers, a segment in the first or second region and parallel to the seam, the segment including a first plurality of structures in a first of the co-planar device or metallization layers, the first plurality of structures arrayed in a pattern, wherein the seam includes a second plurality of structures in the first of the co-planar device or metallization layers, the second plurality of structures also arrayed in the pattern, and a circuit block of the IC die, the circuit block including first, second, and third sections, and the first and second pluralities of structures arrayed in the pattern, wherein the seam is between the first and second sections, and the segment is between the second and third sections.

In one or more second embodiments, further to the first embodiments, the segment extends a first width of the circuit block, the seam extends a second width of the IC die, and the second width is greater than the first width.

In one or more third embodiments, further to the first or second embodiments, the segment is a first segment, also including a second segment in the circuit block and parallel to the seam, the second segment including a third plurality of structures in the first of the co-planar device or metallization layers, the third plurality of structures also arrayed in the pattern.

In one or more fourth embodiments, further to the first through third embodiments, the segment is a first segment, the pattern is a first pattern, and the circuit block is a first circuit block, also including a second circuit block and a second segment parallel to the seam, wherein the second segment includes a third plurality of structures in the first of the co-planar device or metallization layers, the third plurality of structures is arrayed in a second pattern, the seam includes a fourth plurality of structures in the first of the co-planar device or metallization layers, and the fourth plurality of structures is also arrayed in the second pattern.

In one or more fifth embodiments, further to the first through fourth embodiments, the first of the co-planar device or metallization layers includes first active structures in the first region and second active structures in the second region, also including first and second non-functional walls in one or more co-planar metallization layers in the plurality of co-planar metallization layers, the first non-functional wall between the first active structures and the second non-functional wall, and the second non-functional wall between the second active structures and the first non-functional wall.

In one or more sixth embodiments, further to the first through fifth embodiments, the first of the co-planar device or metallization layers includes first active structures in the first region and second active structures in the second region, also including a third region around the first active structures in the first region and the second active structures in the second region, and a third non-functional wall in the third region and around the first active structures in the first region and the second active structures in the second region.

In one or more seventh embodiments, further to the first through sixth embodiments, the apparatus also includes fourth and fifth non-functional walls, wherein the fourth non-functional wall is between the third non-functional wall and the first active structures in the first region, and the fifth non-functional wall is between the third non-functional wall and the second active structures in the second region.

In one or more eighth embodiments, further to the first through seventh embodiments, the first of the co-planar device or metallization layers including the structures arrayed in the pattern includes active features of the first region in a first lithographic field of the IC die and active features of the second region in a second lithographic field of the IC die.

In one or more ninth embodiments, further to the first through eighth embodiments, the first and second lithographic fields include high numerical aperture extreme ultraviolet lithographic fields.

In one or more tenth embodiments, further to the first through ninth embodiments, a second co-planar metallization layer of the plurality of co-planar metallization layers includes a third lithographic field including a first area of the first lithographic field and a second area of the second lithographic field.

In one or more eleventh embodiments, further to the first through tenth embodiments, the first of the co-planar device or metallization layers includes first active features in the first region and second active features in the second region, and wherein a second of the plurality of co-planar metallization layers includes a metal line extending over the seam and between the first and second regions.

In one or more twelfth embodiments, further to the first through eleventh embodiments, the seam includes a seam width equal to or greater than 10 μm.

In one or more thirteenth embodiments, an apparatus includes an integrated circuit (IC) device on a substrate, the device including a seam between first and second regions of the substrate and crossing a functional block of the IC device, the first and second regions including co-planar device layers and a plurality of co-planar metallization layers, and a segment in the functional block and parallel to the seam, wherein the segment includes a first plurality of non-functional structures in a first of the co-planar device or metallization layers, the seam includes a second plurality of non-functional structures in the first of the co-planar device or metallization layers, the first and second pluralities of non-functional structures are arrayed in a matching pattern, the seam separates first and second sections of the functional block, and the segment separates the second and a third section of the functional block.

In one or more fourteenth embodiments, further to the thirteenth embodiments, the first of the co-planar device or metallization layers includes first active structures in the first region and second active structures in the second region, and wherein a second of the co-planar metallization layers includes a metal line extending over the seam and between the first and second regions.

In one or more fifteenth embodiments, further to the thirteenth or fourteenth embodiments, the apparatus also includes a third region around the first and second active structures, wherein the seam extends into the third region, and the seam includes a third plurality of non-functional structures in the first of the co-planar device or metallization layers in the third region.

In one or more sixteenth embodiments, further to the thirteenth through fifteenth embodiments, the IC device is a first IC device, the seam is a first seam, also including a second IC device on the substrate, wherein the second IC device includes a second seam between third active structures in a fourth region and fourth active structures in a fifth region, the third region is around the third and fourth active structures in the second IC device and between the third and fourth active structures in the second IC device and the first and second active structures in the first IC device, and the second seam in the second IC device does not extend into the third region.

In one or more seventeenth embodiments, further to the thirteenth through sixteenth embodiments, the first IC device includes a first guard ring between the third region and at least the first active structures, the second IC device includes a second guard ring between the third region and at least the third active structures, and the third region is between the first and second guard rings.

In one or more eighteenth embodiments, a method includes exposing a first lithographic field of a photoresist layer over a substrate, exposing a second lithographic field of the photoresist layer adjacent the first lithographic field, and forming a layer of one of device structures or metallization structures in first and second regions of the substrate using the exposed first and second lithographic fields of the photoresist layer, the layer including a lithographic seam between the first and second regions, the layer also including a functional unit over the lithographic seam with a first portion in the first and a second portion in the second region, and the lithographic seam including lithographic registration marks and metrology structures patterned in said exposing the first or second lithographic fields.

In one or more nineteenth embodiments, further to the eighteenth embodiments, the method also includes exposing a third lithographic field of a second photoresist layer over the substrate, wherein the third lithographic field includes the first and second regions, and forming a metallization layer in the first and second regions of the substrate using the exposed third lithographic field, wherein the metallization layer includes a metal line extending over the lithographic seam.

In one or more twentieth embodiments, further to the eighteenth or nineteenth embodiments, the method also includes singulating first, second, and third dies from the substrate, wherein the first die is within the first region, the second die is within the second region, the third die is within an area of the third lithographic field and overlaps with the first and second regions, and the lithographic seam crosses the third die.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
first and second regions of an integrated circuit (IC) die and a seam therebetween, wherein the first and second regions comprise co-planar device layers and a plurality of co-planar metallization layers;
a segment in the first or second region and parallel to the seam, the segment comprising a first plurality of structures in a first of the co-planar device or metallization layers, the first plurality of structures arrayed in a pattern, wherein the seam comprises a second plurality of structures in the first of the co-planar device or metallization layers, the second plurality of structures also arrayed in the pattern; and
a circuit block of the IC die, the circuit block comprising first, second, and third sections, and the first and second pluralities of structures arrayed in the pattern, wherein the seam is between the first and second sections, and the segment is between the second and third sections.

2. The apparatus of claim 1, wherein the segment extends a first width of the circuit block, the seam extends a second width of the IC die, and the second width is greater than the first width.

3. The apparatus of claim 2, wherein the segment is a first segment, further comprising a second segment in the circuit block and parallel to the seam, the second segment comprising a third plurality of structures in the first of the co-planar device or metallization layers, the third plurality of structures also arrayed in the pattern.

4. The apparatus of claim 1, wherein the segment is a first segment, the pattern is a first pattern, and the circuit block is a first circuit block, further comprising a second circuit block and a second segment parallel to the seam, wherein the second segment comprises a third plurality of structures in the first of the co-planar device or metallization layers, the third plurality of structures is arrayed in a second pattern, the seam comprises a fourth plurality of structures in the first of the co-planar device or metallization layers, and the fourth plurality of structures is also arrayed in the second pattern.

5. The apparatus of claim 1, wherein the first of the co-planar device or metallization layers comprises first active structures in the first region and second active structures in the second region, further comprising first and second non-functional walls in one or more co-planar metallization layers in the plurality of co-planar metallization layers, the first non-functional wall between the first active structures and the second non-functional wall, and the second non-functional wall between the second active structures and the first non-functional wall.

6. The apparatus of claim 1, wherein the first of the co-planar device or metallization layers comprises first active structures in the first region and second active structures in the second region, further comprising a third region around the first active structures in the first region and the second active structures in the second region, and a third non-functional wall in the third region and around the first active structures in the first region and the second active structures in the second region.

7. The apparatus of claim 6, further comprising fourth and fifth non-functional walls, wherein the fourth non-functional wall is between the third non-functional wall and the first active structures in the first region, and the fifth non-functional wall is between the third non-functional wall and the second active structures in the second region.

8. The apparatus of claim 1, wherein the first of the co-planar device or metallization layers comprising the structures arrayed in the pattern comprises active features of the first region in a first lithographic field of the IC die and active features of the second region in a second lithographic field of the IC die.

9. The apparatus of claim 8, wherein the first and second lithographic fields comprise high numerical aperture extreme ultraviolet lithographic fields.

10. The apparatus of claim 8, wherein a second co-planar metallization layer of the plurality of co-planar metallization layers comprises a third lithographic field comprising a first area of the first lithographic field and a second area of the second lithographic field.

11. The apparatus of claim 1, wherein the first of the co-planar device or metallization layers comprises first active features in the first region and second active features in the second region, and wherein a second of the plurality of co-planar metallization layers comprises a metal line extending over the seam and between the first and second regions.

12. The apparatus of claim 1, wherein the seam comprises a seam width equal to or greater than 10 μm.

13. An apparatus, comprising:
an integrated circuit (IC) device on a substrate, the device comprising:
a seam between first and second regions of the substrate and crossing a functional block of the IC device, the first and second regions comprising co-planar device layers and a plurality of co-planar metallization layers; and
a segment in the functional block and parallel to the seam, wherein the segment comprises a first plurality of non-functional structures in a first of the co-planar device or metallization layers, the seam comprises a second plurality of non-functional structures in the first of the co-planar device or metallization layers, the first and second pluralities of non-functional structures are arrayed in a matching pattern, the seam separates first and second sections of the functional block, and the segment separates the second and a third section of the functional block.

14. The apparatus of claim 13, wherein the first of the co-planar device or metallization layers comprises first active structures in the first region and second active structures in the second region, and wherein a second of the co-planar metallization layers comprises a metal line extending over the seam and between the first and second regions.

15. The apparatus of claim 14, further comprising a third region around the first and second active structures, wherein the seam extends into the third region, and the seam comprises a third plurality of non-functional structures in the first of the co-planar device or metallization layers in the third region.

16. The apparatus of claim 15, wherein the IC device is a first IC device, the seam is a first seam, further comprising a second IC device on the substrate, wherein the second IC device comprises a second seam between third active structures in a fourth region and fourth active structures in a fifth region, the third region is around the third and fourth active structures in the second IC device and between the third and fourth active structures in the second IC device and the first and second active structures in the first IC device, and the second seam in the second IC device does not extend into the third region.

17. The apparatus of claim 16, wherein the first IC device comprises a first guard ring between the third region and at least the first active structures, the second IC device comprises a second guard ring between the third region and at least the third active structures, and the third region is between the first and second guard rings.

18. A method, comprising:
exposing a first lithographic field of a photoresist layer over a substrate;
exposing a second lithographic field of the photoresist layer adjacent the first lithographic field; and
forming a layer of one of device structures or metallization structures in first and second regions of the substrate using the exposed first and second lithographic fields of the photoresist layer, the layer comprising a lithographic seam between the first and second regions, the layer further comprising a functional unit over the lithographic seam with a first portion in the first and a second portion in the second region, and the lithographic seam comprising lithographic registration marks and metrology structures patterned in said exposing the first or second lithographic fields.

19. The method of claim 18, further comprising:
exposing a third lithographic field of a second photoresist layer over the substrate, wherein the third lithographic field comprises the first and second regions; and
forming a metallization layer in the first and second regions of the substrate using the exposed third lithographic field, wherein the metallization layer comprises a metal line extending over the lithographic seam.

20. The method of claim 19, further comprising singulating first, second, and third dies from the substrate, wherein the first die is within the first region, the second die is within the second region, the third die is within an area of the third lithographic field and overlaps with the first and second regions, and the lithographic seam crosses the third die.
